(19) United States
(12) Patent Application Publication
(10) Pub. No.: US 2026/0136749 A1
(43) Pub. Date: May 14, 2026

(54) PEROVSKITE PHOTOVOLTAIC STRUCTURES

(71) Applicant: Energy Materials Corporation, Rochester, NY (US)

(72) Inventors: Thomas Nathaniel Tombs, Rochester, NY (US); Scott Kenneth Christensen, North Chili, NY (US); Garrett Jacob Vander Stouw, Rochester, NY (US)

(21) Appl. No.: 19/115,482

(22) PCT Filed: Sep. 29, 2023
(86) PCT No.: PCT/US2023/034137

§ 371 Date: Mar. 26, 2025

(30) Foreign Application Priority Data
Sep. 30, 2022 (US) 63/411892
Jul. 17, 2023 (US) 63/527218

(51) Int. Cl. H10K 30/83; H10K 30/40; H10K 30/50; H10K 30/82; H10K 85/50; H10K 102/10; H10K 102/20

(52) U.S. Cl. CPC H10K 30/83; H10K 30/40; H10K 30/50; H10K 30/821; H10K 85/50; H10K 2102/101; H10K 2102/20

(57) ABSTRACT

A bifacial photovoltaic structure includes a transparent substrate, a light-transmissive bottom electrode, a perovskite absorber layer disposed over the bottom electrode, and a transparent top electrode disposed over the perovskite absorber layer. The light-transmissive bottom electrode includes a first set of conductive lines disposed on the substrate and a first conducting layer disposed over the first set of conductive lines. The first conducting layer includes a conductive carbon material.

### CROSS-REFERENCE TO RELATED APPLICATIONS

This application claims priority to, and any other benefit of U.S. Provisional Patent Application Ser. No. 63/411,892 entitled PHOTOVOLTAIC STRUCTURES HAVING A

COMPOSITE CONDUCTOR, filed Sep. 30, 2022, and to U.S. Provisional Patent Application Ser. No. 63/527,218 entitled PEROVSKITE PHOTOVOLTAIC STRUCTURES, filed Jul. 17, 2023, the entire disclosures of which are fully incorporated herein by reference.

### TECHNICAL FIELD

The present disclosure relates to perovskite photovoltaic devices having a light-transmissive composite conductor, and in particular, to bifacial perovskite photovoltaic devices.

### BACKGROUND

Since their first report in 2009, rapid improvements have enabled perovskite solar cells (PSCs) to become a promising technology for converting light to electricity as part of optoelectronic devices. To date, the power conversion efficiencies (PCEs) of solution-processed PSCs have been certified above 25 percent, which is higher than the current dominant photovoltaic (“PV”) technology based on multi-crystalline silicon. Whereas crystalline silicon is rigid, brittle, and requires costly, energy-intensive fabrication procedures, perovskites are flexible, easily processed at low temperatures, and up to a thousand times thinner. Furthermore, perovskites are solution-processable, which enables their manufacture with scalable, low-cost methods. These attributes open new opportunities to integrate solar power creatively and inexpensively into previously inaccessible markets, such as electric vehicles and buildings. PSCs also have the important advantage of maintaining acceptable PCE as the temperature increases, unlike silicon-based solar cells, which exhibit significant power loss in typical operating environments. The manufacturing and PCE advantages of PSCs have put them on the path to be the next generation technology for utility, commercial, and residential photovoltaic applications.

Most top performing PSCs reported in the literature have been fabricated by lab-scale, spin-coating methods, which are unsuitable for high throughput and scalable module production. Forming high-performing, uniform, and defect-free multilayer structures on flexible substrates to make PSCs in a cost-effective manner remains a great challenge. Some of this complexity is due to the complexity of depositing and drying a perovskite solution with high-speed production equipment, but other layers can be challenging as well. Some non-limiting factors to consider in the manufacture of multilayer PSCs may include the adhesion of one layer to another, the chemical compatibility of a coating solution with an underlying layer, thermal treatments and compatibility of such with other layers, surface energy or structures and their effect on coatability, layer flexibility, thermal expansion properties, and optical properties, just to name a few.

High efficiency PSCs benefit from electrodes that have low electrical resistance and high optical transparency, but such electrodes can be difficult to produce at high manufacturing speeds in a manner compatible with other layers of the PSC. Low resistance electrodes are particularly desired for high area devices where photogenerated currents may need to travel a significant distance to current collectors or other device components. Higher resistance across a long path can result in an unacceptable power efficiency loss. The challenges are further heightened when both electrodes are light transmissive, such as in bifacial photovoltaic structures. Bifacial solar cells can receive light from the front or back and generate electricity, but cost-effective methods and materials for making such structures have been elusive.

Despite research into various approaches, PVs based primarily on perovskites have yet to make a large market impact due at least in part to some of the unresolved problems noted above.

### SUMMARY

There remains a desire for PSC devices that can be reliably manufactured at large scale at low cost, have high PCEs, and that can be made having large sizes or surface areas without unacceptable power loss.

In accordance with an embodiment of this disclosure, a bifacial photovoltaic structure configured for receiving and converting a target wavelength or wavelength range of light to electricity includes a transparent substrate, which is transparent to the target wavelength or wavelength range of light; a light-transmissive bottom electrode, which is transmissive to the target wavelength or wavelength range of light; a perovskite absorber layer disposed over the bottom electrode; and a transparent top electrode, which is transparent to the target wavelength or wavelength range of light, disposed over the perovskite absorber layer. The light-transmissive bottom electrode includes a first set of conductive lines disposed on the substrate and a first conducting layer disposed over the first set of conductive lines. The first conducting layer includes a conductive carbon material.

In accordance with another embodiment, a method of making an electrode structure useful as a bottom electrode for a photovoltaic structure is described including providing a substrate structure having a first set of conductive lines disposed on a transparent substrate, wherein the transparent substrate is transparent to a target wavelength or wavelength range of light; and conveying the substrate structure to a first conducting layer station where a first conducting layer is formed over the first set of conductive lines to form a light-transmissive bottom electrode. The first conducting layer comprises a conductive carbon material and is transmissive to the target wavelength or wavelength range of light. The first conducting layer may be printed in a pattern corresponding to individual photovoltaic cells to be connected in series.

In some embodiments, the materials, structures, and methods of the present disclosure, e.g., those relating to the bottom electrode, provide an improved balance between transparency, manufacturing costs, and/or overall performance of bifacial perovskite PV structures. The PV devices of the present disclosure may have one or more of the following advantages relative to conventional PV devices: improved PCE; lower resistance electrodes; electrodes with higher optical transparency; improved manufacturing scalability; simplified manufacturing process; lower manufacturing cost; reduced manufacturing defects; more reproducible manufacturing process; reduced environmental impact manufacturing process; increased physical durability or increased lifetime.

### BRIEF DESCRIPTION OF DRAWINGS

FIG. 1 is a cross-sectional view of a non-limiting example of a perovskite photovoltaic structure according to some embodiments.

FIG. 2A is a cross-sectional view of non-limiting examples of conductive lines according to some embodiments.

FIG. 2B is a top view of a non-limiting example of a set of conductive lines according to some embodiments.

FIG. 2C is a top view of a non-limiting example of a set of conductive lines according to some embodiments.

FIG. 3 is a cross-sectional schematic of first and second sets of conductive lines according to some embodiments.

FIG. 4A is a cross-sectional view of a portion of a photovoltaic structure illustrating embedded conductive lines.

FIG. 4B is a cross-sectional view of a portion of a photovoltaic structure illustrating another embodiment of embedded conductive lines.

FIG. 4C is a cross-sectional view of a portion of a photovoltaic structure illustrating another embodiment of embedded conductive lines.

FIG. 5A is photograph of a resistance measurement tool according to some embodiments.

FIG. 5B illustrates certain dimensions of the resistance measurement tool.

FIG. 5C illustrates an orientation of the resistance measurement tool to a composite conductor.

FIG. 5D illustrates another orientation of the resistance measurement tool to a composite conductor.

FIG. 6 is a schematic diagram illustrating a photovoltaic structure manufacturing system according to some embodiments.

### DETAILED DESCRIPTION

It is to be understood that the drawings are for purposes of illustrating the concepts of the disclosure and may not be to scale. Terms like “overlaying”, “over” or the like include, but do not necessarily require, direct contact (unless such direct contact is noted or clearly required for functionality). Additional details of certain embodiments of the present application may be found in U.S. Pat. Nos. 11,108,007, 11,342,130, U.S. Application No. 2020/0377532, and U.S. Application Publication No. 2022/0238807, the entire contents of which are incorporated herein by reference for all uses.

A perovskite photovoltaic (PV) structure is intended to receive light (typically visible, IR, or UV light) and convert it into electricity. As such, various layers and features may need to be reasonably transparent to this light to ensure that an appropriate amount reaches the perovskite absorber layer(s). Herein, unless otherwise noted, the terms “transparent”, “transparency”, “transmissive”, “transmittance”, or the like, are generally relative to the target wavelength or wavelength range for conversion to electricity. This target wavelength or wavelength range may be different for different systems. In some embodiments, the target wavelength range may correspond to the solar radiation spectrum or a portion thereof. In some cases, the target wavelength range may correspond to the visible light spectrum or a portion thereof. In some cases, the target wavelength range may correspond to the infrared or UV spectrum, or a portion thereof. In some embodiments, the target wavelength range may be defined as a particular wavelength, e.g., 400 nm, 450 nm, 500 nm, 550 nm, 600 nm, 650 nm, 700 nm, or 750 nm, or any other wavelength of interest in the IR, visible, or UV portions of the spectrum intended for energy conversion. In some cases, a target wavelength range may be defined as an explicit range, e.g., 400-425 nm, 425-450 nm, 450-475 nm, 475-500 nm, 500-525 nm, 525-575 nm, 575-600 nm, 600-625 nm, 625-650 nm, 650-675 nm, 675-700 nm, 700-725 nm, 725-750 nm, or any combination of ranges thereof, or any other wavelength range of interest.

In some embodiments, something (e.g., a layer, a component, a structure, or the like) that is “transparent” transmits at least 50% of incident radiation within the target wavelength range, i.e., a transmittance (% T) of 50%. Something that is considered light transmissive generally transmits at least 10% of incident radiation within the target wavelength range. Transmittances in the range of 10% up to 50% may be considered partially transparent. A light-transmissive component, layer, or structure may be either transparent or partially transparent.

Besides the light-absorbing properties of a layer, a component, a structure, or the like, its apparent transparency may in some cases be affected by refractive index mismatches, surface structures, or other factors that may result in reflective losses and/or light scattering. Another way to describe transparency is in terms of absorptance (% A). In some embodiments, something that is “transparent” may have an absorptance of 50% or less with respect to incident radiation within the target wavelength range. Something that is considered light transmissive may have an absorptance of 90% or less of incident radiation within the target wavelength range. Absorptances in a range of 50% up to 90% may be considered partially transparent. PV Structure Overview

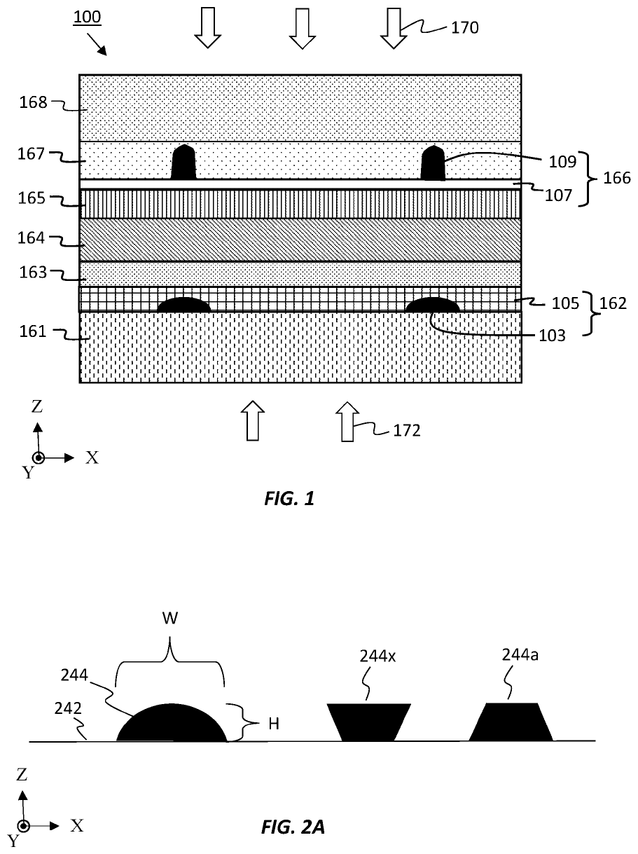

FIG. 1 is a cross-sectional view of a non-limiting example of a perovskite photovoltaic structure according to some embodiments. For added perspective, XYZ coordinate axes are also shown. The photovoltaic structure 100 may include a light-transmissive substrate 161, e.g., a transparent substrate, which may in some cases be flexible. A light-transmissive bottom electrode 162 may be provided overlaying the transparent substrate 161. The bottom electrode may include a first set of conductive lines 103 and a first conducting layer 105 provided over and in contact with the first set of conductive lines. Such an electrode structure may optionally be referred to as a composite conductor, herein. The conductive lines should have metallic conductivity, and in many embodiments, it is preferred that the conductive lines are metal lines. For convenience, conductive lines may sometimes be referred to herein as metal lines, but the terms are interchangeable unless context indicates otherwise. In some preferred embodiments, the first conducting layer may include a conductive carbon material such as carbon nanotubes, graphene, graphene oxide, or the like. Although illustrated as a planarizing coating, the first conducting layer may in some cases be partially planarizing or even conformally coated.

A first carrier transport layer 163 may be provided overlaying the first composite conductor. If the underlying conducting layer has high surface roughness, then it may be advantageous for the first carrier transport layer 163 to be planarizing or at least partially planarizing (rather than conformal) so that the surface roughness at the top of the first carrier transport layer is lower than that of the first conducting layer. A perovskite absorber layer 164 may be provided overlaying the first carrier transport layer. A second carrier transport layer 165 may be provided overlaying the perovskite absorber layer.

A transparent top electrode 166 may be provided overlaying the second carrier transport layer. In some cases, the transparent top electrode may be a second composite conductor including a second conducting layer 107 and a second set of conductive lines 109 (e.g., metal lines 109) provided in contact with the second conducting layer. In some embodiments, when using a composite conductor, the second set of conductive lines are generally not in direct contact with the second carrier transport layer 165. That is, and as shown in FIG. 1, the second conducting layer may be provided over the second carrier transport layer and the second set of conductive lines may be provided over the second conducting layer. This may be preferred particularly if the second set of conductive lines includes highly diffusing metal such as silver. Use of a transparent conductive oxide as the conducting layer may in some cases provide a good barrier to such diffusion.

In some other embodiments, not shown, the second set of conductive lines may be provided over the second carrier transport layer and the second conducting layer may be provided over the second set of metal lines and over the second carrier transport layer. This may be suitable when the second set of conductive lines does not include a highly diffusing metal, when an interfacial layer is provided between the conductive lines and the perovskite layer, or when the second carrier transport layer is resistant to metal diffusion. An example of the latter may be the use of a copper compound as the second carrier transport layer and copper metal for the conductive lines. Alternatively, use of a tin oxide as the second carrier transport layer may also resist metal diffusion (silver or copper). In some other embodiments, the top electrode includes one or more transparent conducting layers and no metal lines at all.

In some embodiments, the photovoltaic structure may optionally include a transparent adhesion layer 167 provided over the top electrode 166. In some cases, the second set of conductive lines (if used) may be substantially embedded within the adhesion layer 167. Adhesion layer 167 may in some cases have planarizing properties, act as an encapsulation layer, or both. In some embodiments, 167 may be referred to as an encapsulation layer that in part functions to reduce the ingress of water or other materials to improve device lifetime. In some cases, the photovoltaic structure may optionally include a transparent superstrate 168 provided over adhesion layer 167. In some embodiments, the transparent superstrate may be flexible. In some cases, the adhesion layer 167 may be first applied over the second composite conductor and the transparent superstrate may be adherently applied over the adhesion layer. In some embodiments, the adhesion layer 167 is pre-applied to the superstrate 168 and that assembly may be laminated to the top electrode.

The layers between the bottom and top electrodes shown in FIG. 1 may sometimes be referred to herein as photovoltaic “active layers”. Although not illustrated in FIG. 1, in some embodiments, one or more interfacial layers may optionally be provided between any adjacent active layers, between an active layer and an electrode, over the top electrode or under the bottom electrode. Herein the term “interfacial layer” is used broadly, with the purpose, e.g., of altering one or more properties of the interface between two layers such as changing the work function, increasing the barrier properties to mobile ions, passivating defects in a neighboring layer, or altering the band gap. In some cases, an interfacial layer may more specifically act as a barrier to diffusion of water, solvents, molecules, ions (e.g., metal ions and/or halide ions). In some embodiments an interfacial layer may passivate, deactivate or otherwise ameliorate unwanted trap states or carrier transport barriers at layer interfaces or even grain boundaries. An interfacial layer may in some embodiments include a generally electrically insulating metal oxide (e.g., aluminum oxide, titanium dioxide, or the like) that is sufficiently thin so as not to seriously impede the transport of charge between layers. In some embodiments, an interfacial layer may be less than 6 nm, alternatively less than 2 nm. In some cases, an interfacial layer may be a few monolayers thick, alternatively a single monolayer thick. In some cases, an interfacial layer may be a continuous layer or film, but in other cases may be discontinuous. In some embodiments, an interfacial layer may be applied by an inline tool compatible with roll-to-roll manufacturing. In some cases, an interfacial layer may be applied by spatial ALD (SALD), a reduced pressure metal oxide deposition tool, or coating (or other contact) with a solution, liquid, gas, or aerosol that includes an interfacial material. Additionally, anywhere the phrase “interfacial layer” or similar concepts appear herein, they may be replaced by “interfacial treatment”. In some cases, an interfacial treatment may not result in deposition of an interfacial layer but may instead treat a layer at its surface or even internally to provide the desired treatment result.

Photovoltaic structure 100 may advantageously be a bifacial photovoltaic structure capable of receiving light 170 from its upper surface and light 172 from its lower surface. In some embodiments, light 170 may be more intense than light 172. For example, light 170 may include sunlight and light 172 may include reflected sunlight or some other ambient light source. In such a structure where the top electrode side of the PV device receives the most radiation, the transparency of the top electrode has a significant impact on overall device efficiency. It is therefore important that it be as transparent as possible within cost tolerances. The less intense light that may come through the bottom electrode, e.g., albedo, may be considered “bonus” light, and while providing an increase in overall device efficiency, it may be less important to device performance for the bottom electrode to be highly transparent. It has been found that even partially transparent electrodes may provide an advantageous balance of device efficiency and manufacturing cost. As described elsewhere, the first conducting layer including conductive carbon material is generally too resistive to be used as a bottom electrode by itself and still be light-transmissive. That is, to achieve the desired conductivity, the thickness of the conductive carbon material would make it opaque (not light-transmissive). However, it has been found that an excellent compromise can be made by combining such conductive carbon materials with a pattern of conductive lines in the form of a composite conductor. The first conducting layer can then be applied thinly enough for it to be light-transmissive, but conductive enough to allow charge to transfer to the conductive metal lines which have higher conductivity than the first conducting layer.

In operation, positive and negative charges (holes and electrons) are produced in the perovskite absorber layer 164 in response to absorption of appropriate radiation. The first and second carrier transport layers (163, 165) receive these separated charges and transfer them to the respective first and second composite conductors (162, 166). The bottom and top electrodes may be in electrical contact with an electrical device (not shown in FIG. 1) where the collected charges serve to power the device, or alternatively charge it in the case where the electrical device is an energy storage battery of some sort.

In some embodiments, the first carrier transport layer may include a hole transporting material and the first composite conductor may act as an anode in the photovoltaic structure. In such embodiments, the second carrier transport layer may include an electron transporting material and the second composite conductor may act as a cathode in the photovoltaic structure. Such an arrangement of layers may for convenience be referred to as a PIN structure.

In some alternative embodiments, the first carrier transport layer may include an electron transporting material and the first composite conductor may act as cathode in the photovoltaic structure. In such embodiments, the second carrier transport layer may include a hole transporting material and the second composite conductor may act as an anode in the photovoltaic structure. Such an arrangement of layers may for convenience be referred to as a NIP structure.

In some embodiments, the materials and methods used for forming one or more layers of the photovoltaic structure are compatible with high-speed manufacturing. In some cases, one or more layers may be formed using roll-to-roll processes. In some embodiments, one or more manufacturing steps may instead use batch deposition methods or a series of substrates in a “cut sheet” format, e.g., with each mounted in a frame.

### Transparent Substrate

The transparent substrate is generally electrically insulating and may be formed from any suitable transparent material(s) such as a glass, a polymer (plastic), or a combination of different materials. The transparent substrate may in some cases be rigid, but in preferred embodiments, the transparent substrate is flexible. Some non-limiting examples of transparent substrates may include thin flexible glass such as Corning® Willow® Glass, a polyethylene terephthalate (PET) (which may optionally be a heat-stabilized PET), a polyethylene naphthalate (PEN), a polycarbonate (PC), a polysulfone (PS), a polyether sulfone (PES), a polyamide, p-nitrophenylbutyrate (PNB), a polyetherketone (PEEK), a polyetherimide (PEI), a polyarylate (PAR), a polyvinyl acetate, a polyimide, a cyclic olefin polymer (COP), a cellulose triacetate (TAC), a polyacrylate, or an epoxide. For some applications, some particularly useful transparent substrates include thin flexible glass, PET or heat-stabilized PET. The transparent substrate may optionally include multiple materials or have a multilayer structure. The transparent substrate may include a surface treatment to modify the surface energy for improved coating quality and/or adhesion of subsequent layers. Some non-limiting examples of surface treatments include corona discharge, ozone (created, for example, with ultraviolet radiation), and plasma. Surface treatment devices may operate in ambient air, conditioned air (where temperature and relative humidity are controlled), oxygen, or inert gas such as nitrogen or argon. In some embodiments, a surface-modifying treatment may involve a wet chemical treatment or even an additional surface layer deposited by a wet- or dry-coating method. In some cases, a surface layer may be referred to as a primer layer. In some cases, the transparent substrate may act as a water vapor or oxygen barrier, e.g., through choice of substrate material or by addition of one or more barrier layers.

Note that by “flexible” it is generally meant that the material can undergo some shape changes at least in one dimension in response to some force or stress without significant damage. In some cases, flexibility of a substrate or material may be measured by its bend radius, which is the minimum radius that it can be bent without functionally damaging it. In some embodiments, a flexible transparent support may have a bend radius of less than 100 cm, alternatively less than 50 cm, 20 cm, 10 cm, 5 cm, 4 cm, 3 cm, 2 cm, or 1 cm. In some preferred embodiments, a flexible transparent substrate may have a bend radius of less than 10 cm.

There are no particular limitations on the thickness of the substrate if flexibility is not desired, so long as it remains sufficiently transparent. In some preferred embodiments, a flexible transparent substrate is suitable for roll-to-roll manufacturing and may have a thickness of less than about 350 μm if it is flexible glass (e.g., a thickness in a range of 50 to 350 μm), or alternatively less than about 250 μm or alternatively less than 200 μm if it is a flexible plastic (e.g., a thickness in a range of 20 to 250 μm or alternatively 20 to 200 μm). The transparent substrate preferably has a transmittance (% T) of at least 80%, or more preferably 90%. Alternatively, the transparent substrate preferably has an absorptance (% A) of less than 20%, or more preferably, less than 10%.

### First and Second Carrier Transport Layers

As mentioned, one carrier transport layer includes a hole transporting material, and the other carrier transport layer includes an electron transporting material. A carrier transport material that includes a hole transporting material may be referred to as a hole transport layer. In addition to transporting holes, a hole transporting material may also effectively block the transport of electrons. A carrier transport material that includes an electron transporting material may be referred to as an electron transport layer. In addition to transporting electrons, an electron transporting material may also effectively block the transport of holes. In some embodiments, a carrier transport layer may include multiple layers of materials. A non-limiting example of a multilayer charge transport layer may include embodiments where one sublayer is especially for transporting the desired charge and another sublayer is especially for blocking the opposite charge. In some cases, a blocking sublayer may be adjacent to the perovskite absorber layer. The thickness of a carrier transport layer depends in part on the properties of the overall photovoltaic stack, but in some embodiments, may have an average thickness in a range of 10's to 100's of nanometers.

Some non-limiting examples of hole-transporting materials may include a poly(triaryl amine) (e.g., poly[bis(4-phenyl) (2,4,6-trimethylphenyl)amine]), a poly-(N-vinyl carbazole), PEDOT complex, a poly(3-hexylthiophene), spiro-MeOTAD (also known as N²,N²,N²′,N²′,N⁷,N⁷,N⁷,NT-octakis (4-methoxyphenyl)-9,9′-spirobi[9H-fluorene]-2,2′,7,7′-tetramine), poly-TPD, EH44, certain metal oxides (e.g. nickel oxide, molybdenum oxide, and vanadium oxide, any of which may optionally be doped), copper thiocyanate, copper bromide and copper iodide, and certain self-assembled monolayers (e.g. 2-(9H-Carbazol-9-yl)ethyl] phosphonic acid, sometimes referred to as 2PACz)

Some non-limiting examples of electron-transporting materials may include fullerenes, (e.g., phenyl-C61-butyric acid methyl ester (PCBM) and fullerene-C60), bathocuproine (BCP), TPBI, PFN, PC71BM, ICBA, graphene, reduced graphene oxide, certain metal oxides (e.g., tin oxide, zinc oxide, cerium oxide, and TiO₂, any of which may optionally be doped).

Depending in part upon the particular material, a carrier transport layer may in some cases be deposited by a dry deposition process. Some non-limiting examples of dry processes may include sputtering, thermal evaporation, physical vapor deposition, chemical vapor deposition, atomic layer deposition, e-beam deposition, or some other process that may in some cases operate under reduced pressure. In some cases, dry deposition may be performed inline in a roll-to-roll system, e.g., by using spatial ALD (SALD) or a reduced pressure material deposition (RPMD) tool. Such RPMD tools operate at pressures above normal vacuum deposition systems, e.g., in a range of 0.01 mBar to 200 mBar. In some embodiments, a carrier transport layer may be deposited from an aerosol of nanoparticles. Some non-limiting examples of aerosol-based deposition are described in U.S. Pat. No. 10,092,926, which is incorporated by reference herein in its entirety for all purposes. In some cases, aerosol deposition has been found to be less damaging to underlying device layers.

In some embodiments, a carrier transport layer may be deposited by a coating process that does not require reduced pressure. Some non-limiting examples of coating processes may include gravure, slot die, spray, dip coat, inkjet, flexographic, rod, or blade coating methods. In some cases, a coating process may be followed by a thermal treatment to drive off solvent, anneal the carrier transport material, or the like.

In some embodiments, a carrier transport layer may be deposited by transfer of the carrier transport material from a donor sheet, e.g., by application of heat or some other stimulus to release it from the donor sheet with adherent transfer to the appropriate device layer or substrate.

In some preferred cases, the deposition method is suitable for high-speed manufacturing. In some embodiments, the deposition of one or more carrier transport layers may be performed using a roll-to-roll manufacturing process.

For systems having NIP type structures, it can be advantageous for the first carrier transport layer to include tin oxide and the second carrier transport layer to include a copper compound such as copper thiocyanate, copper bromide, or copper iodide. Such NIP systems may advantageously further include the use of copper metal lines in the top electrode. In some embodiments the copper lines may be over a second conducting layer, or alternatively, the copper lines may be over the copper compound carrier transport layer and the second conducting layer is provided over the copper lines.

### Perovskite Absorber Layer

Perovskite materials and methods for forming perovskite absorber layers may be as described in U.S. Pat. Nos. 11,108,007, 11,342,130, U.S. Application No.

2020/0377532, and U.S. Application Publication No. 2022/0238807, the entire contents of which are incorporated herein by reference. In some embodiments, a perovskite absorber layer may be coated from a fluid mixture, which may be referred to as a perovskite solution. Any coating method suitable for coating a fluid mixture may be used including, but not limited to, gravure, slot die, spray, dip coat, inkjet, flexographic, rod, or blade coating methods. In some cases, the perovskite deposition method is suitable for high-speed manufacturing. In some embodiments, a perovskite absorber layer may be performed using a roll-to-roll manufacturing process. The term “perovskite solution” refers to a solution or colloidal suspension that can be used to generate a continuous layer of organic-inorganic hybrid perovskite material (the perovskite absorber layer), e.g., one with an ABX₃ crystal lattice where ‘A’ and ‘B’ are two cations of very different sizes, and X is an anion that coordinates to both cations. A perovskite solution typically includes an appropriate set of perovskite precursor materials and one or more solvents in which the precursor material is dissolved or suspended. A perovskite solution may also contain additives, e.g., to aid in crystal growth or to modify crystal properties or for some other purpose. A perovskite precursor material is typically an ionic species where at least one of its constituents becomes incorporated into the final perovskite layer ABX₃ crystal lattice. Organic perovskite precursor materials are materials whose cation contains carbon atoms while inorganic perovskite precursor materials are materials whose cation contains metal but does not contain carbon.

When the perovskite solution dries, perovskite crystals or an intermediate precursor phase for hybrid perovskite crystals (intermediate phase) form. The intermediate phase is a crystal, adduct, or mesophase that is not the desired final crystal lattice, which is ABX₃. The intermediate phase, if present, may be converted to the desired final crystal lattice by annealing. In some cases, annealing or other heating methods may include the use of heated nip rollers, optionally under nitrogen.

Some non-limiting examples of inorganic perovskite precursor materials for making perovskite solutions may include lead (II) iodide, lead (II) acetate, lead (II) acetate trihydrate, lead (II) chloride, lead (II) bromide, lead nitrate, lead thiocyanate, tin (II) iodide, rubidium halide, potassium halide, and cesium halide. In some cases, the halide may include iodide. Some non-limiting examples of organic perovskite precursor materials for making perovskite solutions may include methylammonium iodide, methylammonium bromide, methylammonium chloride, methylammonium acetate, formamidinium bromide, and formamidinium iodide. To produce a high-performance perovskite device, it is generally preferred in some cases that the organic perovskite precursor material has a purity greater than 99 percent by weight and the inorganic perovskite precursor has a purity greater than 99.9 percent by weight. The inorganic perovskite precursor material contains a metal cation, and in some preferred embodiments, the metal cation is lead. In some preferred embodiment, the molar ratio of organic perovskite precursor material to inorganic perovskite precursor material may be in a range of one to three.

In some cases, a perovskite solution may be formulated using a large proportion of a low boiling point solvent (e.g., at least 50 wt. % of total solvent, preferably at least 75 wt. % of total solvent, more preferably at least 90 wt. % of total solvent). In some embodiments, a low boiling point solvent is one having a boiling point of less than 150° C., or preferably less than 135° C.

Such proportions may assist or enable high speed production of a uniform perovskite layer. Using an appropriate drying method, a low boiling point solvent can be made to evaporate quickly from the perovskite solution after deposition on a substrate thus minimizing movement of the crystals that form as the perovskite solution dries. Solvents that do not strongly coordinate with the perovskite precursors further enable short annealing times. Short annealing times are desirable because they enable higher production speeds. Alcohol-based solvents have been identified that do not strongly coordinate with the perovskite precursors, can provide the proper solubility of the inorganic precursors, and have been shown to produce a perovskite solution that can be stable for use in high volume manufacturing of perovskite layers and photovoltaic devices. Some non-limiting examples of alcohol-based solvents suitable for use at high proportions in the perovskite solution may include 2-methoxyethanol, 2-ethoxyethanol, 2-butoxyethanol, 2-isopropoxyethanol, methanol, propanol, butanol, and ethanol. Mixtures of solvents are envisioned for use in the perovskite solution to tune the evaporation profile to further optimize the drying process. Some non-limiting examples of suitable solvent additives useful for modifying evaporation rate of the solvent may include dimethylformamide, acetonitrile, dimethyl sulfoxide, N-methyl-2-pyrrolidone, dimethylacetamide, gamma-butyrolactone, phenoxyethanol, acetic acid, and urea.

In some preferred embodiments, a perovskite solution may be formulated with greater than 30 wt. % of solvent (e.g., 30-82 wt. %) and at least 18 wt. % of solids (e.g., 18-70 wt. %, preferably 25-60 wt. %, or 30-45 wt. %), where the total solids concentration of the perovskite solution is in a range of 30-70% by weight of its saturation concentration at the provided solution temperature. In some preferred embodiments, a solution temperature may be in a range of 20-50° C. In some preferred embodiments, the solvent is an alcohol and has a boiling point less than 135° C. In some preferred embodiments, the solvent is 2-methoxyethanol, which has a boiling point of 125° C. In some embodiments, such formulations may provide perovskite solutions that are stable at convenient handling and storage temperatures (e.g., in a range of 20-50° C., and in particular, room temperatures in a range of 20-25° C.), and which can be used to manufacture uniform perovskite layers at high speed, thereby enabling low-cost production of high efficiency solar cells with low equipment costs.

Although uniform perovskite layers have been made at high production speeds with the above formulations, it has sometimes been found that the time required for the perovskite solution to form homogeneous nuclei and grow may be longer than the time required to evaporate the low boiling point solvent in such a way as to produce a uniform perovskite layer. A uniform perovskite layer with optimum sized crystals is desired to make perovskite devices with high photovoltaic energy output. Addition of a crystal growth modifier added to a perovskite solution having a low boiling point solvent has been found to improve the performance of perovskite photovoltaic devices. A crystal growth modifier refers to an additive that either alters the amount of time for homogeneous crystal growth or alters the rate of homogeneous crystal growth when drying a perovskite solution. Some non-limiting examples of crystal growth modifiers that are especially useful in perovskite solutions for making high performance perovskite layers include dimethyl sulfoxide, N-methyl-2-pyrrolidone, gamma-butyrolactone, 1,8-diiodooctane, N-cyclohexyl-2-pyrrolidone, water, dimethylacetamide, acetic acid, cyclohexanone, alkyl diamines, and hydrogen iodide. In some preferred embodiments, the concentration of a crystal growth modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

Another additive for a perovskite solution that may improve the performance of perovskite devices is a crystal grain boundary modifier. A crystal grain boundary modifier refers to an additive that improves the quality of the grain boundary, for example, be altering the electrical properties of the perovskite crystal grain boundary or reducing trap states at perovskite crystal grain boundary interfaces. Some non-limiting examples of crystal grain boundary modifiers that can be particularly useful in perovskite solutions for making high performance perovskite layers include choline chloride, phenethylamine, hexylamine, 1-α-phosphatidylcholine, polyethylene glycol sorbitan monostearate, sodium dodecyl sulfate, Poly(methyl methacrylate), Polyethylene glycol, pyridine, thiophene, ethylene carbonate, propylene carbonate, fullerenes, poly(propylene carbonate), and didodecyldimethylammonium bromide. A preferred concentration of crystal grain boundary modifier may be less than about 10% by weight of the coating solution (e.g., in a range of 0.01-10% wt.). In some cases, a more preferred concentration of crystal growth modifier may be less than about 2% by weight of the coating solution (e.g., 0.01 to 2% wt.).

In some embodiments, particularly in NIP structures, a multifunctional capping layer may be provided between the perovskite absorber layer and the hole transport carrier layer, e.g., as described in US20220246865, which is incorporated by reference herein in its entirety for all purposes. A multifunctional capping layer may include a thiophene-containing molecule functionalized with an ammonium group. A non-limiting example is 2-(3″,4′-dimethyl-[2,2′:5′,2″:5″,2″-quaterthiophen]-5-yl) ethan-1-ammonium iodide.

### Electrodes

Many of the compositions and methods for forming each of the top and bottom electrodes may be individually selected from a similar set of material and coating technology options as described herein. However, in some preferred embodiments, the bottom electrode is generally different in some way relative to the top electrode besides its location in the photovoltaic structure stack. As discussed below, some of these differences may be with respect to material selection, a physical dimension, the deposition method, transmittance (% T), absorptance (% A), or the like. In particular, while the bottom electrode may be a composite conductor structure of conductive lines with an overlying conducting layer of a conductive carbon material, some preferred embodiments of the top electrode may not use such conductive carbon materials due to its need for high transparency.

Despite these differences, it is can also be useful in some embodiments (including, but not limited to, embodiments where a plurality of perovskite photovoltaic structures or cells are connected in series) that the average sheet resistance of the bottom electrode be similar to the average sheet resistance of the top electrode. In some embodiments, the ratio of the average sheet resistance of the bottom electrode to the average sheet resistance of the top electrode may be in a range of 0.2 to 5, alternatively 0.5 to 2, alternatively 0.6 to 1.7, alternatively 0.7 to 1.4, alternatively 0.8 to 1.25, or alternatively 0.9 to 1.1. As discussed elsewhere herein, with respect to composite conductors, the term “sheet resistance” may refer to a functional sheet resistance that depends not only upon the intrinsic resistivities of the conductive lines and the conducting layer, but may also depend upon the geometries of the conductive lines and the intended direction of current flow across the composite conductor.

The transparency of a composite conductor depends on the width of the conductive lines (which are typically mostly opaque), the transparency of the conducting layer, and may also depend in part on the layers adjacent the composite conductors, e.g., on their index of refraction. As mentioned, the bottom electrode is preferably light-transmissive, i.e., it may be partially transparent or transparent, so that the photovoltaic structure may act as a bifacial device. The light-transmissive bottom electrode may have a transmittance % T within a target wavelength range of at least 10%, or alternatively at least 15%, 20%, 25%, 30%, 40%, 50%, 60%, 65%, 70%, 75%, 80%, 85%, 90%, or 95%. In some cases, the bottom electrode may (within a target wavelength range) have a % T in a range of 10-15%, 15-20%, 20-25%, 25-30%, 30-35%, 35-40%, 40-45%, 45-50%, 50-55%, 55-60%, 60-65%, 65-70%, 70-75%, 75-80%, 80-85%, 85-90%, or 90-95%, or any combination of ranges thereof. Higher % T values are usually favored, but other system factors (conductivity, manufacturing cost, device stability . . . , etc.) may also be considered such that the bottom electrode may not have the highest possible % T, but rather have an effective % T for overall device performance.

The light-transmissive bottom electrode may have an absorptance % A within a target wavelength range of less than 90%, or alternatively less than 85%, 80%, 75%, 70%, 60%, 50%, 40%, 35%, 30%, 25%, 20%, 15%, 10%, or 5%. In some cases, the bottom electrode may (within a target wavelength range) have a % A in a range of 5-10%, 10-15%, 15-20%, 20-25%, 25 30%, 30-35%, 35-40%, 40-45%, 45-50%, 50-55%, 55-60%, 60-65%, 65-70%, 70 75%, 75-80%, 80-85%, or 85-90%, or any combination of ranges thereof. Lower % A values are usually favored, but other system factors (conductivity, manufacturing cost, device stability . . . , etc.) may also be considered such that the bottom electrode may not have the lowest possible % A, but rather have an effective % A for overall device performance.

The transparent top electrode may have a % T within a target wavelength range of at least 50%, or alternatively, at least 55%, 60%, 65%, 70%, 75%, 80%, 85%, 90%, or 95%. In some cases, the top electrode may (within a target wavelength range) have a % T in a range of 50-55%, 55-60%, 60-65%, 65-70%, 70-75%, 75-80%, 80-85%, 85-90%, or 90-95%, or any combination of ranges thereof. Higher % T values are usually favored and a significant consideration, but other system factors (conductivity, manufacturing cost, device stability . . . , etc.) may also be considered such that the top electrode may not have the highest possible % T, but rather have an effective % T for overall device performance.

The transparent top electrode may have a % A within a target wavelength range of less than 50%, or alternatively less than 45%, 40%, 35%, 30%, 25%, 20%, 15%, 10%, or 5%. In some cases, the top electrode may (within a target wavelength range) have a % A in a range of 5-10%, 10-15%, 15-20%, 20-25%, 25-30%, 30-35%, 35-40%, 40-45%, or 45-50%, or any combination of ranges thereof. Lower % A values are usually favored, but other system factors (conductivity, manufacturing cost, device stability . . . , etc.) may also be considered such that the top electrode may not have the lowest possible % A, but rather have an effective % A for overall device performance.

In some embodiments, the top electrode may have a higher % T (or lower % A) than the bottom electrode. Alternatively, the bottom and top electrodes may have about the same % T or % A.

### First Conducting Layer

The first conducting layer includes a conductive carbon material that is preferably printable/coatable from mixture. Such printing or coating methods may include ink jet, flexography, gravure, slot die, spray, or the like. Many carbon-based inks are amenable to high-speed coating or printing, e.g., those using roll-to-roll technology at a web speed of greater than 5 m/min or even greater than 30 m/min. This can significantly lower production costs. In some embodiments, the first conducting layer may be printed in a pattern (optionally at high speeds as mentioned above) that may simplify some aspects of manufacturing photovoltaic modules having multiple photovoltaic cells connected in series. For example, a printed first conducting layer may simplify or aid the scribing step(s) that are typically employed in multicell PV device manufacturing.

Conductive carbon materials may include, for example, carbon black, graphite, graphene, graphene oxide, or carbon nanotubes (CNTs). Such materials may be formed into ink slurries and applied. Preferably, the first conducting layer may include CNTs, graphene, graphene oxide, or some combination, since they can provide reasonable transparency and conductivity. In the case of high-aspect ratio CNTs, they may be applied at a density sufficient to form an interconnected, conductive mesh, but low enough to be light transmissive. Unlike many metals, conductive carbon materials are often more compatible with the PV active layers and may provide longer life in some cases due to reduced metal and/or halide diffusion issues. Halide ions such as iodide ions have been found to be mobile in PV devices under some operational conditions. For example, at elevated temperature and/or intense light exposure, halide ions present in the perovskite absorber layer can diffuse and adversely interact with metal conductors such as copper or silver. However, halide ions tend not to interact adversely with conductive carbon materials such as CNTs.

Useful inks may be made by dispersing the conductive carbon material in a solvent, e.g., an alcohol, water, mixtures thereof, or some other substrate-compatible solvent) that may further include binders, surfactants to stabilize the dispersion, and/or rheology control agents. Herein, conductive carbon materials do not include conductive polymers, but the first conducting layer may optionally include a combination of the conductive carbon material (e.g., CNTs, graphene, and/or graphene oxide) and a conductive polymer. A few non-limiting examples of inks that may be useful for the first conducting layer may include, or be based, on those disclosed in U.S. Pat. Nos. 9,868,875, 9,803,097, 11,202,369, US20170029646, or U.S. Pat. No. 9,340,697, the entire contents of each are incorporated by reference in their entirety herein for all purposes. Deposition of the first conducting layer may optionally be followed by a thermal anneal and/or drying treatment. In some embodiments, such thermal anneal or drying step may be performed concurrently with an optional thermal treatment of the underlying conductive lines (anneal, dry, or sinter).

In some embodiments, the applied first conducting layer material may have an intrinsic sheet resistance (i.e., as measured in the absence of the first set of conductive lines) of less than 1500 Ω/square, alternatively less than 1000 Ω/square, or less than 500 Ω/square. In some embodiments, the first conducting layer may have a % T within a target wavelength range of at least 30%, alternatively at least 40%, at least 50%, at least 60%, at least 70%, at least 75%, at least 80%, at least 85%, at least 90%, or at least 95% (as measured in the absence of any conductive lines). In some embodiments, the first conducting layer may have an absorptance % A within a target wavelength range of less than 70%, alternatively, less than 60%, less than 50%, less than 40%, less than 30%, less than 25%, less than 20%, less than 15%, less than 10%, or less than 5%.

In some cases, the first conducting layer may have an intrinsic sheet resistance in a range of 10-100 Ω/square and a % T of at least 50% (or a % A of less than 50%), or alternatively, an intrinsic sheet resistance in a range of 100-250 Ω/square and a % T of at least 70% (or a % A of less than 30%), an intrinsic sheet resistance in a range of 250-500 Ω/square and a % T of at least 75% (or a % A of less than 25%), an intrinsic sheet resistance in a range of 500-750 Q/square and a % T of at least 80% (or a % A of less than 20%), or an intrinsic sheet resistance in a range of 750-1500 Q/square and a % T of at least 85% (or a % A of less than 15%), or an intrinsic sheet resistance of greater than 1500 Q/square and a % T of at least 90% (or a % A of less than 10%).

The thickness of the first conducting layer depends in part on the electrical and optical properties of the selected material and may also depend on the deposition method. In some embodiments, the first conducting layer may have a thickness of less than 500 nm, alternatively less than 200 nm, alternatively less than 100 nm, alternatively less than 50 nm, alternatively less than 20 nm, or alternatively less than 10 nm. When a conducting layer is applied over a set of conductive lines, the average thickness may correspond to areas between the conductive lines. When applied over conductive lines, it is desirable in many cases that the conducting layer also at least partially covers the first set of conductive lines to help ensure electrical continuity and inhibit migration of metal ions into the active layers if the conductive lines are made from metal. In some cases, a surface energy modifying treatment may be applied to the substrate and first set of conductive lines to assist in adhesion and/or uniform deposition of the first conducting layer over both the substrate and the conductive lines.

An additional benefit of providing the first conducting layer over the conductive lines is that the conductive carbon material may in some cases reduce the metal line resistance or even “heal” broken lines. For example, a set of printed silver metal lines running between two bus bars was found to have a line resistance of 11 ohms. After applying a light-transmissive layer of carbon nanotubes, the line resistance had reduced to just 3 ohms (>70% decrease). In some cases, the printed silver metal lines had poor connectivity along their length and adding the CNT layer improved the line resistance, e.g., from >90,000 ohms down to just 32 ohms. In another case where the silver metal lines were apparently broken and not measurable, the added CNT layer provided continuity and a line resistance of 48 ohms.

It may be particularly useful to apply an interfacial layer (discussed elsewhere) over the bottom electrode to at least partially passivate any exposed metal lines that may not be fully covered by the first conducting layer material. For example, due to their high aspect ratio nature, it may be difficult for a CNT-based conducting layer to substantially cover the surface of metal lines.

### Top Electrode Second Conducting Layer

As mentioned, the top electrode may include a second conducting layer alone or in combination with a second set of conductive lines. In some case, the second conducting layer may include high aspect ratio metal nanowires (e.g., silver nanowires) or carbon nanotubes. Such materials may be coated from a dispersion (optionally with a binder, dispersant or the like) at a density sufficient to form an interconnected, conductive mesh, but low enough to maintain transparency. After coating, the conducting layer may optionally be subjected to heating or some other drying step to drive off solvent or otherwise improve conductivity properties of the metal nanowires or carbon nanotubes.

In some embodiments, the second conducting layer may include a conductive polymer material such as PEDOT:PSS, a poly(pyrrole), a polyaniline, a polyphenylene, or a poly(acetylene). Conductive polymers may be applied by a coating from a suspension or solution, e.g., using any of the coating methods described above with respect to the perovskite absorber layer. After coating, the conducting layer may optionally be subjected to heating or some other drying step to drive off solvent or otherwise improve conductivity properties of the conductive polymer.

In some preferred embodiments, the second conducting layer may include doped or undoped metal oxides such as tin oxide (e.g., doped with indium or fluorine), molybdenum oxide, and zinc oxide (e.g., doped with aluminum). Such metal oxides are sometimes referred to as transparent conductive oxides (TCOs). TCOs may in some cases be coated from a suspension of metal oxide particles or formed from a sol-gel precursor solution, typically followed by a heating step to drive off solvent and anneal or sinter the metal oxide particles. TCOs may in some cases be deposited using dry deposition methods such as sputtering, physical vapor deposition, chemical vapor deposition, atomic layer deposition, e-beam deposition, or the like. In some preferred embodiments, a TCO may be deposited from an aerosol of nanoparticles (also considered a dry process). Some non-limiting examples of aerosol-based deposition are described in U.S. Pat. No. 10,092,926, which is incorporated by reference herein in its entirety for all purposes. In some cases, aerosol deposition may be less damaging to underlying device layers. A heating step may optionally follow such dry deposition processes, e.g., to improve conductivity of the deposited layer.

In some preferred embodiments, the second conducting layer may be interposed between the second set of conductive lines and the second charge carrier layer, particularly when the second set of conductive lines are metal lines. Such an arrangement has been found to reduce migration of metal and/or halide ions into the active portion of the perovskite photovoltaic structure. Such migration may cause degradation of performance over time. In some particularly preferred embodiments, the interposing conducting layer includes a TCO as described previously, e.g., indium-doped tin oxide (ITO), fluorine-doped tin oxide (FTO), or aluminum-doped zinc oxide (AZO). The TCO conducting layer may in some cases act as a barrier to diffusion of the metal and/or halide ions.

In some embodiments, the applied second conducting layer may have an intrinsic sheet resistance (i.e., as measured in the absence of conductive lines) of less than 1000 $2/square, preferably less than 500 $2/square, and more preferably less than 300 02/square. In some embodiments, the second conducting layer may have a % T within a target wavelength range of at least 80%, alternatively at least 90%, at least 95%, or at least 97% (as measured in the absence of any conductive lines). In some embodiments, the second conducting layer may have an absorptance % A within a target wavelength range of less than 20%, alternatively, less than 10%, less than 5%, or less than 3%.

The thickness of the second conducting layer depends in part on the electrical and optical properties of the selected material and may also depend on the deposition method. In some embodiments, the second conducting layer may have a thickness of less than 500 nm, alternatively less than 200 nm, alternatively less than 100 nm, alternatively less than 50 nm, alternatively less than 20 nm, or alternatively less than 10 nm. In some embodiments, the conducting layer may be an aerosol-applied TCO having an average thickness in a range of 30 nm to 100 nm.

### Conductive Lines

Unless otherwise noted, the following discussion may apply to the bottom electrode or to the top electrode if it uses a composite conductor.

There is no particular limitation on the conductive material that may be used for the conductive lines. In some preferred embodiments, the conductive lines may be formed of a conductive material having a conductivity of at least 105 S/m. In many embodiments, the conductive material includes a metal. In some embodiments, metal lines may include silver or copper, or alloys containing one or both of these metals. In some cases, other metals may be suitable including, but not limited to, gold, aluminum, molybdenum, tungsten, zinc, nickel, iron, tin, palladium, platinum, titanium, and alloys containing one or more of these metals.

In some embodiments, the conductive line material may include a non-metal such as a conductive carbon material containing, for example, graphite, graphene, graphene oxide, carbon nanotubes or the like. A material or ink similar to that described for the first conducting layer may be used, albeit the properties of the ink may be adjusted for use as conductive lines. To provide the necessary conductivity and serve the intended function of the conductive lines, conductive carbon materials generally need to be thicker and wider than many metals. Wider is often not acceptable for the second set of metal lines since it may reduce transparency too much. Wider may be acceptable for the first set of metal lines since transparency is less important, but thick (tall) conductive lines can potentially be problematic coating layers over the bottom electrode when making PV structures similar to those illustrated in FIG. 1.

In some embodiments, conductive lines may be deposited using a dry deposition process coupled with some patterning process. For example, conductive lines may be deposited by thermal evaporation, sputtering, physical vapor deposition, chemical vapor deposition, atomic layer deposition, e-beam deposition, or the like. Patterned conductive lines may be formed, for example, by deposition through a shadow mask or by using known photolithographic methods that may involve etching and/or lift-off processes. In some embodiments, a metal layer may be electrochemically or electrolessly deposited and then patterned into metal lines, for example, by photolithography. In some embodiments, conductive lines may be deposited by transfer of prepatterned conductive lines from a donor sheet to the intended surface, optionally in combination with heat and/or pressure.

In some embodiments, conductive lines may be formed by printing. In some embodiments, printing may involve patterned application of an electroless metallization catalyst (e.g., palladium) followed by contact with an electroless plating solution (e.g., copper or nickel). In some preferred embodiments, metal lines may be printed using a metal-containing fluid mixture or “metal ink” (e.g., a suspension, slurry, paste, or the like). In some cases, printing metal lines may be performed by flexographic printing, inkjet printing, screen printing, gravure printing, or some other printing technology. The printed metal lines may in some cases be followed by a heat treatment to drive off solvent or cause metal particles to fuse or sinter, which can increase the metal conductivity. Heat treatments may include an oven, IR heaters, flashlamps, heated rollers (with or without pressure), or the like. Plasma may also be used to sinter metal particles. U.S. Pat. No. 8,907,258, incorporated herein by reference for all purposes, discloses a non-limiting example of a pulsed radiation apparatus that may be suitable for metal particle sintering in a roll-to-roll manner. In some cases, a printed metal ink may be subjected to a secondary chemical treatment such as a reducing agent. The metal ink may include metal particulates of various shapes and sizes (e.g., spherical, oblong, nanoparticles, nanowires, plates) in an appropriate liquid carrier and may further include other agents such as binders, surfactants, or the like. A few non-limiting examples of metal inks may include those disclosed in US20220025200, which is incorporated herein by reference for all purposes. In some embodiments, a surface receiving the metal ink may first be treated to modify its surface energy, e.g., by corona discharge, a plasma, UV/ozone, or a chemical treatment. Modification of this surface energy can in some cases be used to control the shape, dimension, and/or adhesion of the deposited metal ink.

The particular set of conductive materials and patterning methods may be different for the first set of conductive lines 103 relative to the (optional) second set of conductive lines 109. For example, when forming the first set of conductive lines 103, substrate 161 may have a relatively wide tolerance for ink solvents, plating, photolithography, heat treatments, surface treatments, and the like. However, when forming the second set of conductive lines 109, the conducting layer 107 and underlying charge transport 165 and perovskite 164 layers may have a lower tolerance for these materials and treatments. In some embodiments, the second set of conductive lines may be preferably formed using technology other than photolithography or plating, in particular, printing is preferred. In some preferred embodiments, the second set of metal conductive lines may be printed using flexography which has been found in some cases to cause less physical damage to sensitive underlying layers relative to some other contact printing methods such as gravure or screen printing. Flexography can also provide very fine line dimensions, which may be beneficial in some cases. In some cases, screen printing may be preferred, e.g., when thick metal lines are desired. In some cases, gravure printing may be preferred, e.g., when very high printing speeds are desired. In some cases, non-contact printing such as inkjet may be preferred, e.g., when the underlying layers are particularly sensitive to physical contact. In some preferred embodiments, both the first set of conductive lines and a second set of conductive lines are formed by printing from an ink.

### Conductive (Metal) Line Patterns

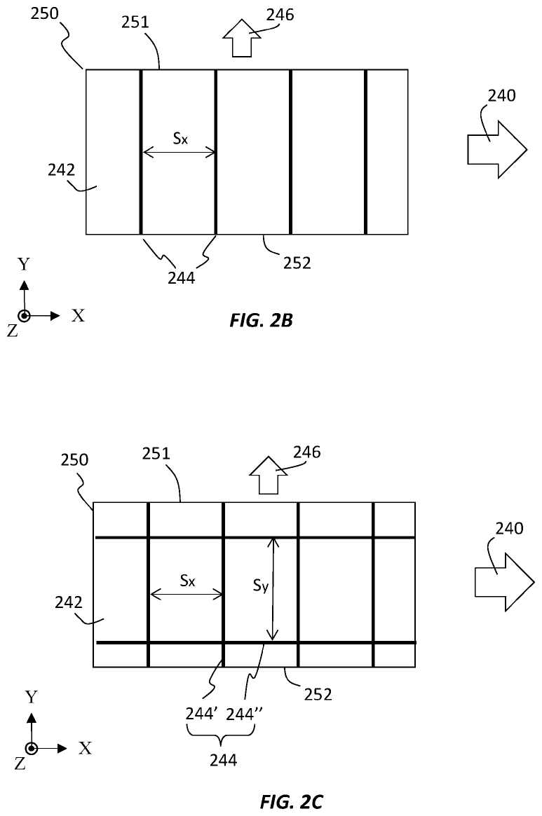

FIG. 2A is a cross-sectional view of non-limiting examples of conductive lines according to some embodiments. Conductive line 244 may be provided on a surface 242. A conductive line may be characterized in cross section by a height H (or thickness) and width W. Height H and width W may be measured at a particular point or may be reported as an average height H and average width W along a conductive line. In some embodiments, the height or width may vary along the length of a conductive line.

Surface 242 may correspond to the surface of a substrate when conductive line 244 is part of the first set of conductive lines. Alternatively, surface 242 may correspond to the upper portion of the second conducting layer when conductive line 244 is part of the second set of conductive lines. Conductive line 244 may take on a variety of shapes and sizes. In FIG. 2A, conductive line 244 is shown to have a hemispherical shape in cross-section, but such a shape is not limiting. In some embodiments, in particular for the first set of conductive lines, it may be less preferred to use conductive line structures such as conductive line 244x where the top of the metal is wider than the base thereby creating an overhang. This may create electrical discontinuities when depositing the first conducting layer over the first set of conductive lines, particularly when the first conducting layer is substantially thinner than the conductive line. Even a substantially vertical sidewall (e.g., a square or rectangular shape in cross section) may in some cases result in electrical discontinuities or areas of metal that are not covered such that the first conducting layer cannot act as an effective metal ion barrier. In some preferred embodiments, the cross-sectional shape of the conductive line may have sidewalls that generally slope (as projected away from surface 242) inwardly toward the middle of the line, e.g., as shown in conductive line 244a or even 244. Although shown as symmetrical, the cross-sectional shape may not be symmetrical.

FIG. 2B is a top view of a non-limiting example of a set of conductive lines according to some embodiments. As with FIG. 2A, surface 242 may correspond to the surface of a substrate when the set of conductive lines 244 represents the first set of conductive lines. Alternatively, surface 242 may correspond to the upper portion of the second conducting layer when the set of conductive lines 244 represents a second set of conductive lines. In some cases, the conductive lines may be provided by roll-to-roll coating as discussed, and arrow 240 may correspond to the direction of web conveyance. Alternatively, arrow 240 may correspond to the direction of a cut sheet conveyance. The set of conductive lines may be characterized by an average spacing Sx. In some preferred embodiments, the conductive lines may be substantially parallel to each other and uniformly spaced. By substantially parallel, it is meant that the conductive lines are non-intersecting and generally align within 30° of each other relative to a common axis along a length dimension, alternatively within 15°, 10°, 5°, 3°, 2°, or even within 1°. “Uniformly spaced” may refer to an average standard deviation of the spacings that is less than about 20% of an average spacing. The conductive lines may be substantially parallel to the Y axis in FIG. 2B. When using roll-to-roll coating, such conductive lines may be advantageously provided having a direction substantially orthogonal to the web conveyance direction, e.g., when using flexographic printing methods for the conductive lines. In some cases, however, the conductive lines may be provided at a different angle, or at various angles. Similarly, in some cases, the spacing may not be uniform. Although shown as straight lines, the conductive lines could include some curvature, a zig-zag pattern, or some other pattern.

In operation, positive or negative charges may generally flow in a direction 246, substantially parallel to the set of conductive lines, to a first edge 251 of cell 250 where the current may be collected by a bus line or transferred in series to an adjacent cell (not shown). Although not shown, opposite charges may flow in the direction opposite of arrow 246 to the second edge 252 of cell 250 to be collected by a bus line or transferred in series to an adjacent cell

FIG. 2C is a top view of a non-limiting example of a set of conductive lines according to some embodiments. FIG. 2C is similar to FIG. 2B, but in addition to conductive lines 244′ parallel to the Y axis, may further includes conductive lines 244″ orthogonal to the conductive lines 244′ and parallel to the X axis or conveyance direction 240. The set of conductive lines includes both 244′ and 244″. The conductive lines 244″ may be characterized by an average spacing Sy. In some preferred embodiments, the conductive lines may be substantially parallel to each other and uniformly spaced. However, other angles and spacing options may be used in a manner similar to that discussed with respect to conductive lines 244′. Conductive lines 244″ may be applied in the same step as 244′, or alternatively, may be made separately and/or using a different deposition technology. The width of the conductive lines 244′ may be about the same as conductive lines 244″, but in some other embodiments, they may be smaller or larger. The set of conductive lines may make a crossed-line grid as shown, or may include a honeycomb shape, or some other pattern. Although adding the set of conductive lines 244″ as shown in FIG. 2C may in some cases reduce the overall transparency of the composite conductor relative to FIG. 2B, it may in some cases mitigate the effect of defects or discontinuities of conductive lines 244′ to ensure that charges generated in cell 250 can be transported to cell edge 251 or 252 without high resistance. In some embodiments, S_{y}>Sₓ. In some cases, the ratio of S_{y} to Sₓ may be greater than 1.5, alternatively greater than 2, alternatively greater than 3, or alternatively greater than 5. In this way, the impact on transparency may be reduced while still providing low resistance pathways in the event of a discontinuity in a conductive line 244′.

A photovoltaic structure may be characterized by an active area, e.g., corresponding to the area of cell 250 in the XY plane that includes the active layers and which is intended to receive light in order to generate electricity. Conductive lines such as 244 occupy some of the active area and block light. The conductive lines (dimensions, #of lines, etc.) should be provided in a manner to yield the desired conductivity, but not block more light than necessary. In some embodiments, a first set of conductive lines may occupy less than 40% of the active cell surface area, alternatively less than 30%, less than 25%, less than 20%, less than 15%, less than 10%, or even less than 5%, In some cases a second set of conductive lines may occupy an active cell surface area in a range of 1% to 20%, or alternatively 2% to 10%. In some embodiments a second set of conductive lines may occupy less than 15% of the active cell surface area, preferably less than 10%, more preferably less than 5%. In some cases, a second set of conductive lines occupies an active cell surface area in a range of 0.5% to 10%, or alternatively 1 to 5%. In some cases, the average spacing Sₓ of the conductive lines is in a range of 0.1 to 2.0 mm. In some cases, a ratio Sₓ/W of average spacing Sₓ of the conductive lines to the average width W of the conductive lines is in a range of 10 to 100. In some embodiments, the average width W of the conductive lines of the first or second set of conductive lines is less than 40 μm, preferably less than 30 μm. In some embodiments, the average width W of the conductive lines of the first or second set of conductive lines may be in a range of 1 to 30 μm, alternatively 2 to 25 μm. In some embodiments, the average height H of the conductive lines of the first or second set of conductive lines is at least 50 nm, preferably at least 100 nm.

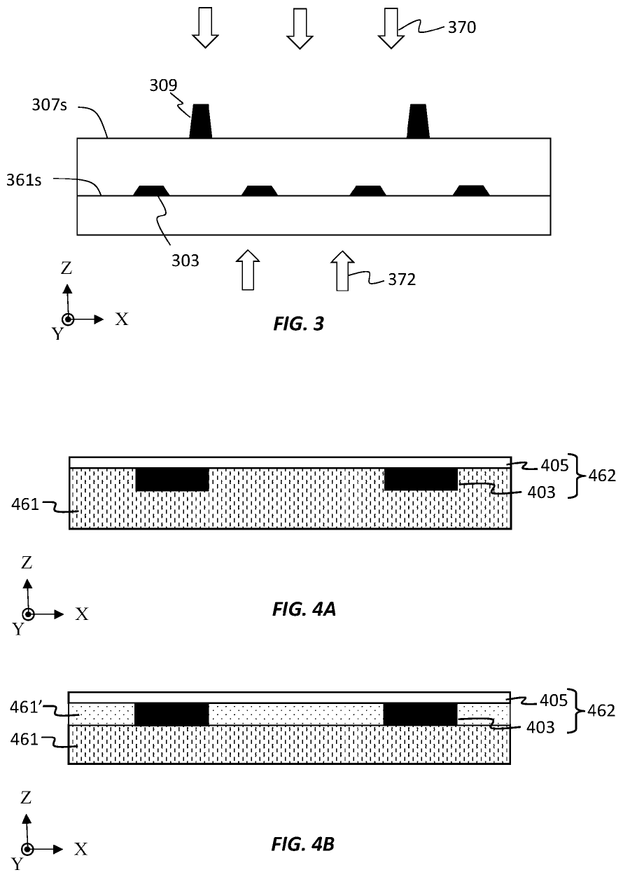

FIG. 3 is a cross-sectional schematic of first and second sets of conductive lines according to some embodiments. FIG. 3 may be considered analogous to FIG. 1 but simplified to show just the sets of conductive lines and the surfaces on which they are applied. A first set of conductive lines 303 may be provided in a first pattern on a surface 361s which may correspond to an upper surface of a substrate. A second set of conductive lines 309 may be provided on surface 307s, which may correspond to an upper surface of the second conducting layer.

In some embodiments, the first set of conductive lines 303 is different in some way relative to the second set of conductive lines (if present), besides the location in the photovoltaic stack. In some cases, this difference may be with respect to at least one physical dimension (spacing, height, width, line direction, any ratios thereof, or the like). With respect to physical dimensions, such difference may be at least 5%, alternatively at least 10%, alternatively at least 20%, or alternatively at least 50%. For example, the spacings between the first set of conductive lines may be different than the spacings of the second set of conductive lines. In FIG. 3, the spacing of second set of conductive lines 309 is greater than the spacing of the first set of conductive lines 303. This may be preferred in some embodiments where more intense light 370 is expected to be received through the top of the structure relative to light 372 received through the bottom. For example, the top of the structure may be laminated to a window or the like that faces sunlight, and the bottom of the structure may receive less intense ambient room light through the substrate. However, in alternative embodiments, the spacing of the second set of conductive lines may be equal to or even less than that of the first set of conductive lines.

In some cases, the average width of the first set of conductive lines may be different than the second set of conductive lines (if present). As shown in FIG. 3, the first set of conductive lines may be wider than the second set of conductive lines. This may be preferred in some embodiments where more intense light 370 is expected to be received through the top of the structure relative to light 372 received through the bottom. In some embodiments, the average width W1 of the first set of conductive lines may be in a range of 15 to 40 μm, whereas the average width W2 of the second set of conductive lines may be in a range of 2 to 20 μm. In some printing embodiments, the width of the conductive lines may in part be controlled by adjusting the surface energy of the surface on which they are printed. For example, matching a surface energy to an ink may allow for more spreading of the ink and produce wider lines. A mismatch in surface energy may reduce the amount of ink spreading and produce narrower lines.

In some cases, the first set of conductive lines may be characterized by a ratio Sx1/W1 of average spacing Sx1 of the first conductive lines to the average width W1 of the first conductive lines. Similarly, the second set of conductive lines (if present) may be characterized by a ratio Sx2/W2 of average spacing Sx2 of the second conductive lines to the average width W2 of the second conductive lines. In some embodiments Sx2/W2 is at least 5% greater than Sx1/W1, alternatively at least 10% greater, at least 20% greater or at least 50% greater.

Whether by spacing or line width or both, in some embodiments, the second set of conductive lines (if present) may in some cases block less light, i.e., have a higher % T (lower % A) than the first set of conductive lines. Alternatively, or in combination, in some cases the % T (or % A) of the second composite conductor may about the same as the % T (or % A) of the first composite conductor. Again, higher % T for the second set of conductive lines and the second composite conductor may be preferred where more intense light 370 is expected to be received through the top of the structure relative to light 372 received through the bottom. However, in alternative embodiments, the average width of the second set of conductive lines may be equal to or even greater than average width of the first set of conductive lines.

In some cases, the average height of the first set of conductive lines may be different than the average height of the second set of conductive lines (if present). As shown in FIG. 3, the second set of conductive lines 309 may be thicker (greater height) than the first set of conductive lines 303. By keeping the first set of conductive lines relatively short, it is easier for the first conducting layer to be coated in a manner that more reliably covers the conductive lines. Further, low-height first conductive lines may be better suited for the contiguous deposition of other device layers which may have thicknesses on the order of 10's to 100's of nanometers. If the height of the bottom conductive lines are too high, the composite bottom electrode structure may induce discontinuities in the thin overlaying active layers. In some embodiments, the average height of the first set of conductive lines may be less than 300 nm, preferably less than 200 nm, more preferably less than 150 nm. For example, in some cases the average height H1 of the first set of conductive lines may be in a range of about 20 200 nm, alternatively in a range of 50 150 nm. In some cases, the second set of conductive lines may have a height of greater than 50 nm, alternatively greater than 100 nm, alternatively greater than 200 nm, or alternatively greater than 500 nm. For example, in some cases the average H2 of the second set of conductive lines may be in a range of 200-1500 nm. In some embodiments when printing a second set of conductive lines, it may be difficult to fully sinter the conductive material (e.g., a metal) without damaging the underlying perovskite or other layers. As such, the intrinsic resistivity of the conductive line material may be higher than for a fully sintered conductive line material. In such cases it may be preferred to deposit a thicker conductive line to compensate. However, in some alternative embodiments, the second set of conductive lines may have about the same height or even a lower height relative to the first set of conductive lines.

In some embodiments, a second set of conductive lines may, as shown in FIG. 3, have a combination of narrower width, greater height, and greater spacing, relative to the first set of conductive lines. In some cases, the second set of conductive lines may substantially align with the first set of conductive lines (e.g., FIG. 1), alternatively, they may not align (e.g., FIG. 3), or in other embodiments, some may align while others may not.

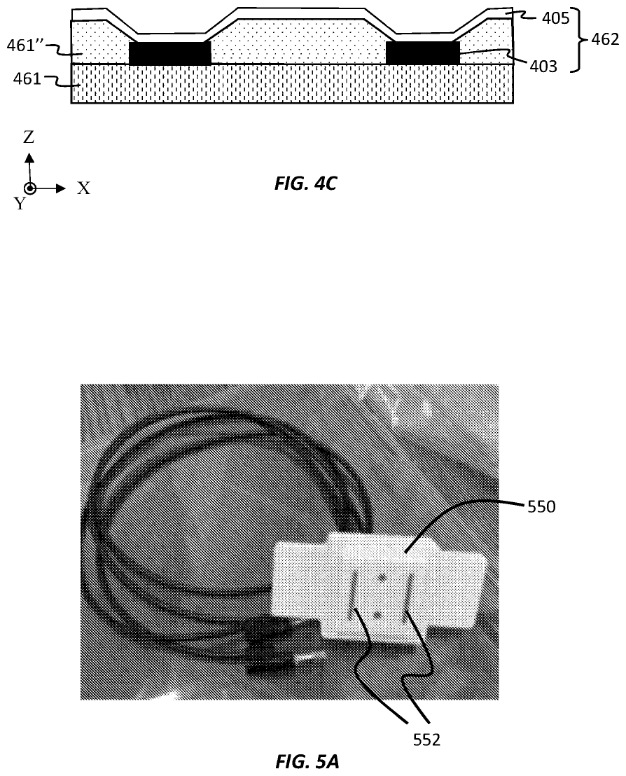

In some embodiments, the first set of conductive lines may be embedded in the substrate. FIG. 4A is a cross-sectional view of a portion of a photovoltaic structure illustrating embedded conductive lines. A first set of conductive lines 403 may be embedded in substrate 461 such that the top surface of the conductive lines may approximately match the top surface of substrate 461. The first conducting layer 405 may smoothly overlay the substrate and embedded conductive lines to form composite conductor 462. In some cases, the conductive line surface may be above or below the plane of the substrate surface, but in such cases, it may be preferred that this displacement is less than the thickness of the first conducting layer or the total device structure. The conductive lines may be embedded using a variety of methods. For example, a prepatterned doner sheet having the conductive lines may be pressed into a substrate under temperature and pressure to partially melt the upper area of the substrate and allow transfer of the embedded conductive lines with removal of the donor sheet. Alternatively, a substrate material may be melt-cast over a pattern of conductive lines on a donor surface, and upon cooling, the solid polymer substrate may be peeled away along with the conductive lines.

FIG. 4B is a cross-sectional view of a portion of a photovoltaic structure illustrating another embodiment of embedded conductive lines. FIG. 4B may be similar to FIG. 4A except that it includes a patterned smoothing layer 461′ over substrate 461, and the top surface of the smoothing layer 461′ may approximately match the top surface of the conductive lines 403. In some cases, the patterned smoothing layer may be made from a photosensitive polymer such as a photoresist. For example, a first set of conductive lines may be patterned on substrate 461. A negative-type photoresist layer may be applied over the substrate and conductive lines, and exposed with an appropriate patterning radiation wavelength from the back (through the substrate). The conductive lines may act as an in situ optical mask. Upon development, the exposed resist remains in place between the conductive lines, while areas of the photoresist that had been above the lines are developed away.

FIG. 4C is a cross-sectional view of a portion of a photovoltaic structure illustrating another embodiment of embedded conductive lines. FIG. 4C may be similar to FIG. 4B except that the patterned smoothing layer 461″ may include a taper near the edge of the conductive lines 403 to allow a continuous coating of the first conducting layer 405 even though portions of the smoothing layer may extend higher than the surface of the conductive lines (higher even than the thickness of the electrically conducting layer). Such a smoothing layer may also be provided by photosensitive polymers or photolithographic methods.

In some cases, embedded conductive lines may be metal lines. In some other embodiments, embedded conductive lines may include a non-metal conductive material such as a conductive carbon material as discussed elsewhere. Because the carbon-based conductive lines are embedded, a conductive carbon material (carbon-based conductive line material) can be relatively thick (deep) to provide sufficient electrical conductivity without compromising the layer structure or making it difficult to coat other active layers over the bottom electrode. In this way, a bottom electrode can be fabricated without the use of any transition metals (a metal-free bottom electrode), which as mentioned, are sometimes problematic due to metal diffusion into other active layers. A substantially metal-free bottom electrode generally includes less than 5% (w/w) of transition metal elements, alternatively less than 2%, 1%, 0.5%, 0.1%, 0.05%, 0.01%, 0.005%, or 0.001%. A carbon-based conductive line may be formed of the same or similar conductive carbon material used for the first conducting layer, or it may be different. An embedded carbon-based conductive line generally at least 2× thicker than the first conducting layer, alternatively in a range of 2×-3× thicker, 3×-4× thicker, 4×-5× thicker, 5×-7× thicker, 7× 10× thicker, or any combination of ranges thereof, or even more than 10× thicker.

### Functional Sheet Resistance Metrics

Although the conductivity or resistivity of a composite conductor can be described in party by intrinsic properties of the conductive lines and conducting layer materials, it is important to understand the effective conductivity properties of the composite as it may behave in a device architecture. That is, simple sheet resistance measurements may not account for the spatial and directional asymmetries present in a composite conductor. In some cases, a functional or composite sheet resistance may instead be measured or calculated which better correlates to device performance.

For example, in the composite conductor shown in FIGS. 2B and 2C, the primary direction 246 of current flow is in the direction of the conductive lines 244. A functional sheet resistance (R_{functional}) for this composite conductor may in some cases be defined by the geometric and material parameters of the metal lines and conducting layer as according to Equation 1

$${R}_{functional} = \frac{1}{\frac{f * W * H}{{ρ}_{ML} * {S}_{X}} + \frac{1}{{R}_{S , CL}}} \qquad ( 1 )$$

where W is the metal line width (cm), H is the metal line height (cm), f is a dimensionless number that defines the fraction of the W*H cross-section occupied by metal, ρ_{ML} is the metal resistivity (Ω*cm), S_{X} is the average spacing of metal lines in the X-direction (cm), and R_{S,CL} is the sheet resistance of the conducting layer (Ω*▪⁻¹). This functional resistance calculation is useful for composite conductors with conductive lines parallel to direction 246 and composite conductors with conductive lines parallel to directions 246 and 240, but may require modification where lines deviate from these axes, include curvature, or contain zig-zag patterns.

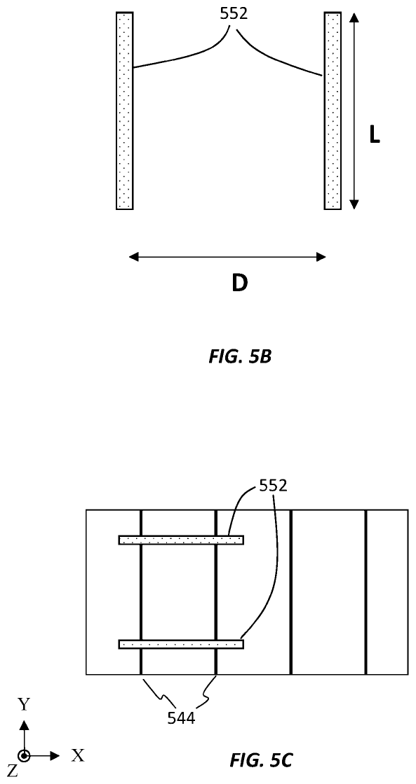

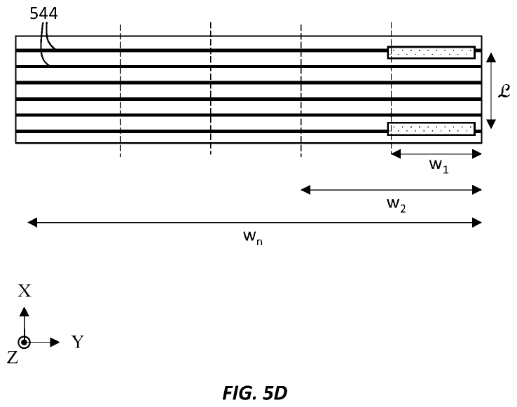

FIG. 5A is photograph of a resistance measurement tool according to some embodiments. FIG. 5B illustrates some dimensions of the resistance measurement tool. Electrical measurement of composite conductors may be achieved using tool 550, which includes two parallel conductors 552 with length L fixed a distance D from one another, connected through a multimeter or other resistance measurement apparatus. Note that L is equal in magnitude to D and corresponds to a probe dimension [symbol] . When resistance of the conductive lines 544 of a composite conductor is sufficiently lower than conducting layer sheet resistance R_{S,CL}, functional sheet resistance may be directly measured by positioning this tool with the measurement probes oriented perpendicular to the conductive line direction as shown in FIG. 5C. Orienting the probes parallel to the conductive line direction as shown in FIG. 5D may also allow approximation of the conducting layer sheet resistance by performing multiple measurements on samples of different width (w₁, w₂ . . . wₙ). Conducting layer sheet resistance may thus be approximated by the slope of a linear fit of measured resistance vs. [symbol] /w, where [symbol] is the probe dimension and w the sample width.

### Adhesion Layer and Superstrate

In some embodiments, the optional adhesion layer may be applied as liquid or gel followed by a curing step, typically while in contact with the superstrate. Some non-limiting examples of curing may include exposure to UV radiation or heat that may cause a chemical reaction such as polymerization. In some cases, the liquid or gel adhesive may first be partially cured prior to contact with the superstrate. In some embodiments, the adhesion layer includes a polymer that does not need UV curing. For example, the adhesion layer may include a pressure sensitive adhesive material. In some preferred embodiments, the adhesion layer is formed by melt lamination (e.g., in a vacuum laminator) of a thermoplastic film. Some non-limiting examples of thermoplastic films may include thermoplastic polyolefins (TPO) such as so-called BPO films available from Quentys, or vinyl acetate-based copolymers such as ethylene-vinyl acetate (EVA) film. The melt lamination step can cause the thermoplastic to become tacky and allow adherent bonding to the superstrate. Further, the thermoplastic has some advantageous encapsulation properties that can help prolong the useful life of the photovoltaic structure. In some cases, TPO films are preferred since EVA may sometimes release acetic acid over time. In some embodiments, the adhesion/encapsulation layer may include a UV absorbing material. In some cases, the adhesion/encapsulation layer may have a thickness in a range of 0.02-1.0 mm, alternatively 0.1-0.8 mm.

The superstrate may be selected from any of the materials listed with respect to the substrate. In some preferred embodiments, the superstrate is glass, which may be flexible or rigid. The superstrate may in some cases be a window or other structure intended to support the photovoltaic structure in operation. In some embodiments, the photovoltaic structure as shown in FIG. 1 may be laminated to a support structure such as a window with second adhesion layer (window and second adhesion layer not shown). Such lamination may be between the substrate and the window, or between the superstrate and the window. In some embodiments, the superstrate may include a UV-absorbing material or layer.

The superstrate may in some cases include one or more optical layers or other features to enhance the transmission of light into photovoltaic structure. For example, the interface of the superstrate with the adhesion layer may include a light scattering layer or surface structure. In some designs, this may reduce the amount of light that may be lost by reflection off the second set of conductive lines.

Although not shown, in some cases when the substrate is plastic, the bottom of the substrate may be bonded to a secondary glass substrate (flexible or solid) by a secondary adhesion layer. This may help to encapsulate the photovoltaic structure and reduce ingress of water or other potentially harmful environmental gases and liquids through the plastic substrate.

### Manufacturing System

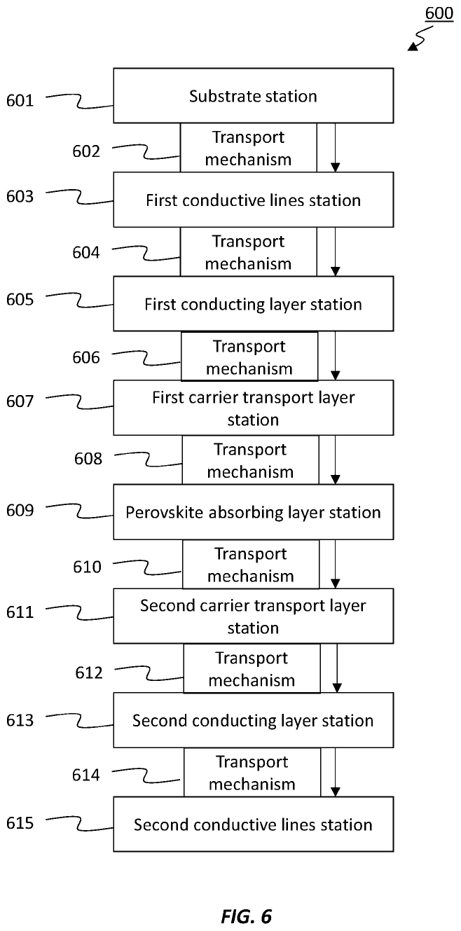

FIG. 6 is a schematic diagram illustrating a photovoltaic structure manufacturing system according to some embodiments. In some preferred embodiments, manufacturing system 600 may use roll-to-roll processing. However, in some cases, the manufacturing system may instead operate using cut sheets. Alternatively, some process steps may be performed using roll-to-roll process and one or more later steps may be performed using cut sheets.

Manufacturing system 600 may include substrate station 601 where transparent substrate material is loaded. In some preferred examples, a roll of substrate material may be provided at substrate station 601. Alternatively, a plurality of precut substrate sheets may be provided, optionally mounted in a frame and/or optionally stacked. For example, the substrate may be flexible glass or a polyester film. Whether from a roll or as a cut sheet, the substrate may be moved to a first conductive lines station 603 via transport mechanism 602. The first conductive lines station 603 may, for example, include a flexographic printing apparatus for printing the first set of conductive lines such as silver metal lines. Prior to forming the first set of conductive lines, the surface of the substrate may in some cases be treated or cleaned (e.g., with an air knife, plasma, corona discharge, or UV/ozone) by a surface treatment apparatus. Note that an “air knife” herein may use a gas other than air, for example, nitrogen. The surface treatment apparatus may be part of the first conductive lines station or part of some earlier station. The first conductive lines station may in some cases further include a conductive line post-treatment apparatus for removing solvent and sintering the conductive line material to improve conductivity. The post-treatment apparatus may include a heating apparatus, for example, an oven, a hot air knife, an IR lamp, a flashlamp, hot roller(s), hot plate(s), compression force, or some combination.

Note that the transparent substrate provided with the first set of metal lines may be referred to herein as a substrate structure. In some other embodiments, a roll or precut sheets of a substrate structure may be used where the first set of metal lines have already been provided in an earlier manufacturing step and there is no need for the first conductive line station.

After forming the first set of conductive lines (or otherwise providing a substrate structure), the film structure may be moved to a first conducting layer station 605 via transport mechanism 604. The first conducting layer station 605 may, for example, include a conductive carbon material deposition apparatus such as a conductive carbon material ink printer or coater. It has been unexpectedly found that gravure coating methods often perform very well with carbon inks (such as CNT-containing inks) relative to slot die coating and some other coating methods. In particular, reduced material clumping (i.e., more uniform material deposition) has been found with gravure coating, e.g., with reverse gravure coating methods. Prior to depositing the first conducting layer, the surface of the film structure may in some cases be treated or cleaned (e.g., with an air knife, plasma, corona discharge, or UV/ozone) by a surface treatment apparatus. The surface treatment apparatus may be part of the first conducting layer station or part of some earlier station. The first conducting layer station may in some cases further include a conducting layer post-treatment apparatus, e.g., a heating apparatus, which may improve the properties of the first conducting layer.

After depositing the first conducting layer, the film structure may be moved to a first carrier transport layer station 607 via transport mechanism 606. For example, the first carrier transport layer station 607 may include a coating apparatus for depositing a first carrier transport material, e.g., by slot die, gravure, ALD, PECVD, or an aerosol-based deposition apparatus. Prior to coating the first carrier layer, the surface of the film structure may in some cases be treated or cleaned (e.g., with an air knife, plasma, corona discharge, or UV/ozone) by a surface treatment apparatus. The surface treatment apparatus may be part of the first carrier layer station or part of some earlier station. The first carrier station may in some cases further include a carrier layer post-treatment apparatus, e.g., a heating apparatus, which may improve the properties of the first carrier layer.

After depositing the first carrier layer, the film structure may be moved to a perovskite absorber layer station 609 via transport mechanism 608. For example, the perovskite absorber layer station 609 may include a coating apparatus for depositing a perovskite material, e.g., by slot die or gravure Prior to coating the perovskite absorber layer, the surface of the film structure may in some cases be treated or cleaned (e.g., with an air knife, plasma, corona discharge, or UV/ozone) by a surface treatment apparatus. The surface treatment apparatus may be part of the first carrier layer station or part of some earlier station. The perovskite absorber layer station may in some cases further include a perovskite layer post-treatment apparatus, e.g., a heating apparatus, for drying the perovskite layer. Drying of the perovskite coating may in some cases utilize a series of heating chambers to control the rate of drying for improved layer performance. In some cases, annealing or other heating methods may include the use of heated nip rollers, optionally under nitrogen.

After depositing the perovskite absorber layer, the film structure may be moved to a second carrier transport layer station 611 via transport mechanism 610. For example, the second carrier transport layer station 611 may include a coating apparatus for depositing a second carrier transport material, e.g., by slot die, gravure, ALD, PECVD, or an aerosol-based deposition apparatus. Prior to coating the second carrier transport layer, the surface of the film structure may in some cases be treated or cleaned (e.g., with air knife, plasma, corona discharge, or UV/ozone) by a surface treatment apparatus. The surface treatment apparatus may be part of the second carrier layer station or part of some earlier station. The second carrier transport station may in some cases further include a carrier layer post-treatment apparatus, e.g., a heating apparatus, which may improve the properties of the second carrier layer.

After forming the second carrier transport, the film structure may be moved to a second conducting layer station 613 via transport mechanism 612. The second conducting layer station 613 may, for example, include a TCO deposition apparatus such as an aerosol-based TCO deposition apparatus. Prior to coating the second conducting layer, the surface of the film structure may in some cases be treated or cleaned (e.g., with an air knife, plasma, corona discharge, or UV/ozone) by a surface treatment apparatus. The surface treatment apparatus may be part of the second carrier layer station or part of some earlier station. The second conducting layer station may in some cases further include a conducting layer post-treatment apparatus, e.g., a heating apparatus, which may improve the properties of the second conducting layer.

After forming the second conducting layer, the film structure may be moved to a second conductive lines station 615 via transport mechanism 614. The second conductive lines station 615 may, for example, include a flexographic printing apparatus for printing the second set of conductive lines such as copper metal lines. Prior to forming the second set of conductive lines, the surface of the substrate may in some cases be treated or cleaned (e.g., with an air knife, plasma, corona discharge, or UV/ozone) by a surface treatment apparatus. The surface treatment apparatus may be part of the second conductive lines station or part of some earlier station. The second conductive lines station may in some cases further include a conductive line post-treatment apparatus for removing solvent and sintering the conductive line material to improve conductivity. The post-treatment apparatus may include a heating apparatus, for example, an oven, a hot air knife, an IR lamp, a flashlamp, hot roller(s), hot plate(s), compression force, or some combination.

Although not shown, manufacturing apparatus 600 may further include stations for depositing one or more interfacial layers over the bottom electrode or between other layers of the photovoltaic device, or applying the adhesive/encapsulation layer, superstrate, cutting, scribing and other operations. Any or all of the stations of manufacturing apparatus 600 may include quality control or inspection tools. Such tools may send data to a central operation station for monitoring the status of manufacturing and optionally to modify the operation of one or more apparatuses to bring it into compliance with operating parameters.

### ENUMERATED EMBODIMENTS

Still further embodiments herein include the following enumerated embodiments.

1. A bifacial photovoltaic structure configured for receiving and converting a target wavelength or wavelength range of light to electricity, including:
a transparent substrate, which is transparent to the target wavelength or wavelength range of light;
a light-transmissive bottom electrode which is transmissive to the target wavelength or wavelength range of light, including a first set of conductive lines disposed on the substrate and a first conducting layer including a conductive carbon material disposed over the first set of conductive lines;
a perovskite absorber layer disposed over the bottom electrode; and
a transparent top electrode, which is transparent to the target wavelength or wavelength range of light, disposed over the perovskite absorber layer.

2. The photovoltaic structure of embodiment 1, wherein the top electrode is more transparent than the bottom electrode.

3 The photovoltaic structure of embodiment 1 or 2, wherein the first set of conductive lines includes silver.

4 The photovoltaic structure according to any of embodiments 1-3, wherein the first set of conductive lines includes copper.

5. The photovoltaic structure according to any of embodiments 1-4, wherein the first set of conductive lines includes a carbon-based conductive line material.

6 The photovoltaic structure according to any of embodiments 1-5, wherein the first conducting layer includes carbon nanotubes.

7. The photovoltaic structure according to any of embodiments 1-6, wherein the first conducting layer includes graphene or graphene oxide.

8. The photovoltaic structure according to any of embodiments 1-7, wherein the transparent top electrode includes a second conducting layer.

9 The photovoltaic structure of embodiment 8, wherein the second conducting layer includes a transparent conductive oxide, metal nanowires, or carbon nanotubes.

10. The photovoltaic structure of embodiment 9, wherein the transparent conductive oxide includes ITO, AZO, or FTO.

11. The photovoltaic structure according to any of embodiments 8-10, wherein the transparent top electrode further includes a second set of conductive lines.

12. The photovoltaic structure of embodiment 11, wherein the second set of conductive lines is disposed over the second conducting layer.

13. The photovoltaic structure of embodiment 11, wherein the second conducting layer is disposed over the second set of conductive lines.

14. The photovoltaic structure according to any of embodiments 11-13, wherein the second set of conductive lines includes a metal.

15. The photovoltaic structure of embodiment 14, wherein the second set of conductive lines includes silver.

16. The photovoltaic structure of embodiment 14 or 15, wherein the second set of conductive lines includes copper.

17. The photovoltaic structure according to any of embodiments 11-16, wherein the second set of conductive lines have an average width that is less than an average width of the first set of conductive lines.

18. The photovoltaic structure according to any of embodiment 11-17, wherein the second set of conductive lines have an average height that is larger than an average height of the first set of conductive lines.

19. The photovoltaic structure according to any of embodiments 1-18, wherein the second set of conductive lines occupies less active cell surface area than the first set of conductive lines.

20. The photovoltaic structure according to any of embodiments 1-19, wherein the first set of conductive lines has an average height in a range of 20-200 nm.

21. The photovoltaic structure according to any of embodiments 1-19, wherein the first set of conductive lines are embedded conductive lines.

22. The photovoltaic structure of embodiment 21, wherein the embedded conductive lines include a carbon-based conductive line material.

23 The photovoltaic structure of embodiment 22, wherein the bottom electrode has a chemical composition including less than 5% (w/w) of transition metal elements.

24. The photovoltaic structure according to any of embodiments 1-23, further including a first carrier transport layer disposed between the bottom electrode and the perovskite absorber layer and a second carrier transport layer disposed between the perovskite absorber layer and the transparent top electrode.

25. The photovoltaic structure of embodiment 24, wherein the first carrier transport layer includes an electron-transporting material and the second carrier transport layer includes a hole-transporting material.

26. The photovoltaic structure of embodiment 25, wherein the hole-transporting material includes a copper compound.

27. The photovoltaic structure of embodiment 26, wherein the copper compound includes CuSCN, CuBr, or CuI, or any combination thereof.

28. The photovoltaic structure according to any of embodiments 25-27, wherein the transparent top electrode includes copper metal lines.

29. The photovoltaic structure according to any of embodiments 25-28, wherein the electron-transporting material includes tin oxide.

30. The photovoltaic structure according to any of embodiments 25-29, further including a capping layer disposed between the perovskite absorber layer and the second carrier transport layer, wherein the capping layer includes a thiophene-containing molecule having an ammonium functional group.

31. The photovoltaic structure of embodiment 24, wherein the first carrier transport layer includes a hole-transporting material and the second carrier transport layer includes an electron-transporting material.

32. The photovoltaic structure of embodiment 31, wherein the hole-transporting material includes nickel oxide or a poly(triaryl amine).

33. The photovoltaic structure of embodiment 31 or 32, wherein the electron-transporting material includes tin oxide.

34. The photovoltaic structure according to any of embodiments 24-33, further including an interfacial layer disposed between the bottom electrode and the first carrier transport layer.

35. The photovoltaic structure according to any of embodiments 24-34, further including an interfacial layer disposed between the first carrier transport layer and the perovskite absorber layer.

36. The photovoltaic structure according to any of embodiments 24-35, further including an interfacial layer disposed between the perovskite absorber layer and the second carrier transport layer.

37. The photovoltaic structure according to any of embodiments 24-36, further including an interfacial layer disposed between the second carrier transport layer and the transparent top electrode.

38. The photovoltaic structure according to any of embodiments 34-37, wherein at least one interfacial layer includes a metal oxide.

39. The photovoltaic structure according to any of embodiments 1-38, wherein the light-transmissive bottom electrode has i) a % T within a target wavelength range of at least 50%, or ii) a % A within a target wavelength range of less than 50%.

40. The photovoltaic structure according to any of embodiments 1-39, wherein the light-transmissive bottom electrode has i) a % T within a target wavelength range of at least 80%, or ii) a % A within a target wavelength range of less than 20%.

41. The photovoltaic structure according to any of embodiments 1-40, wherein the transparent top electrode has i) a % T within a target wavelength range of at least 80%, or ii) a % A within a target wavelength range of less than 20%.

42. The photovoltaic structure according to any of embodiments 1-41, wherein the transparent top electrode has i) a % T within a target wavelength range of at least 90%, or ii) a % A within a target wavelength range of less than 10%.

43. The photovoltaic structure according to any of embodiments 1-42, wherein the transparent substrate has i) a % T within a target wavelength range of at least 90%, or ii) a % A in a target wavelength range of less than 10%.

44. The photovoltaic structure according to any of embodiments 1-43, wherein the target wavelength range is 450-700 nm.

45. The photovoltaic structure according to any of embodiments 1-44, wherein the transparent substrate is flexible.

46. The photovoltaic structure according to any of embodiments 1-45, wherein the transparent substrate includes glass.

47. The photovoltaic structure according to any of embodiments 1-45, wherein the transparent substrate includes PET or PEN

48. The photovoltaic structure according to any of embodiments 1-47, wherein the transparent substrate has a thickness in a range of 50 to 200 μm.

49. A method of making an electrode structure useful as a bottom electrode for a photovoltaic structure, the method including:
providing a substrate structure including a first set of conductive lines disposed on a transparent substrate, wherein the transparent substrate is transparent to a target wavelength or wavelength range of light; and
conveying the substrate structure to a first conducting layer station and depositing a first conducting layer over the first set of conductive lines to form a light-transmissive bottom electrode, wherein the first conducting layer includes a conductive carbon material and is transmissive to the target wavelength or wavelength range of light.

50. The method of embodiment 49, wherein the first conducting layer is printed in a pattern corresponding to individual photovoltaic cells to be connected in series.

51. The method of embodiment 50, wherein the printing of the first conducting layer includes the use of a gravure roller or flexography.

52. The method according to any of embodiments 49-51, wherein the first set of conductive lines are substantially parallel to each other and oriented in a direction substantially orthogonal to a substrate structure conveyance direction.

53. The method according to any of embodiments 49-52, wherein the first set of conductive lines are embedded conductive lines.

54. The method of embodiment 53, wherein the embedded conductive lines include a carbon-based conductive line material.

55. The method according to any of embodiments 49-52, wherein providing the substrate structure includes printing the first set of metal lines onto the transparent substrate.

56. The method of embodiment 55, wherein the printing of the first set of metal lines includes flexographic or screen printing a metal-containing ink.

57. The method of embodiments 55 or 56, wherein the first set of metal lines includes silver.

58. The method according to any of embodiments 55-57, wherein the first set of metal lines includes copper.

59. The method according to any of embodiments 55-58, wherein the first set of metal lines has an average height in a range of 20 to 200 nm.

60. The method according to any of embodiments 49-59, wherein the bottom electrode has i) a % T within a target wavelength range of at least 50%, or ii) a % A within a target wavelength range of less than 50%.

61. The method according to any of embodiments 49-60, further including, conveying the substrate structure to an interfacial layer station and depositing an interfacial layer over the bottom electrode.

62. The method of embodiment 61, wherein depositing the interfacial layer includes spatial atomic layer deposition of a metal oxide.

63. The method according to any of embodiments 49-62, further including conveying the substrate structure to a first carrier transport station and forming a first carrier transport layer over the bottom electrode.

64. The method of embodiment 63, wherein forming the first carrier transport layer includes depositing and drying a liquid first carrier transport material mixture.

65. The method of embodiment 63 or 64, wherein forming the first carrier transport layer includes the use of a gravure cylinder, slot die deposition, anilox cylinder, offset cylinder, or flexography.

66. The method according to any of embodiments 63-65, further including conveying the substrate structure to a perovskite absorber layer station and forming a perovskite absorber layer over the first carrier transport layer.

67. The method of embodiment 66, wherein forming the perovskite absorber layer includes depositing and drying a liquid perovskite absorber material mixture

68. The method of embodiment 65 or 66, wherein forming the perovskite absorber layer includes the use of a gravure cylinder, slot die deposition, anilox cylinder, offset cylinder, or flexography.

69. The method according to any of embodiments 66-68, further including conveying the substrate structure to a second carrier transport station and forming a second carrier transport layer over the perovskite absorber layer.

70. The method of embodiment 69, wherein forming the second carrier transport layer includes depositing and drying a liquid second carrier transport material mixture.

71. The method of embodiment 69 or 70, wherein forming the second carrier transport layer includes the use of a gravure cylinder, slot die deposition, anilox cylinder, offset cylinder, or flexography.

72. The method according to any of embodiments 69-71, further including conveying the substrate structure to a second conducting layer station and forming a second conducting layer over the second carrier transport layer, wherein the second conducting layer includes transparent conductive oxide.

73. The method of embodiment 72, wherein forming the second conducting layer includes depositing an aerosol of transparent conductive oxide particles.

74. The method of embodiment 72, wherein forming the second conducting layer includes spatial atomic layer deposition of the transparent conductive oxide.

75. The method according to any of embodiments 72-74, further including conveying the substrate structure to a second conductive line station and forming a second set of conductive lines over the second carrier transport layer.

76. The method according to any of embodiments 72-74, further including, prior to conveying the substrate structure to the second conducting layer station, conveying the substrate structure to a second conductive line station and forming a second set of conductive lines over the second carrier transport layer, wherein the second set of conductive lines are interposed between the second carrier transport layer and the second conducting layer.

77. The method of embodiment 75 or 76, wherein the second set of conductive lines are substantially parallel to each other and oriented in a direction substantially orthogonal to a transparent substrate conveyance direction.

78. The method according to any of embodiments 75-77, wherein forming the second set of conductive lines includes printing a second set of metal lines.

79. The method of embodiment 78, wherein the printing of the second set of metal lines includes flexographic or screen printing of a metal-containing ink.

80. The method of embodiment 78 or 79, wherein the second set of metal lines includes silver.

81. The method according to any of embodiments 78-80, wherein the second set of metal lines includes copper.

82. The method according to any of embodiments 49-81, wherein the transparent substrate is a flexible substrate that is conveyed in a roll-to-roll manufacturing apparatus to each station.

83. The method according to embodiment 82, wherein the flexible substrate is conveyed through multiple coating stations that are inline in the roll-to-roll manufacturing apparatus.

84. The method according to any of embodiments 49-83, wherein the photovoltaic structure is a bifacial photovoltaic structure according to any of embodiments 1-48.

In addition to their utility in photovoltaic structures, light transmissive bottom electrode structures formed in accordance with the present disclosure may be useful in other electro-optical devices. In particular, such structures having a set of conductive lines disposed over a substrate and a layer of conductive carbon material (e.g., carbon nanotubes) disposed over the conductive lines, may be useful in electrochromic devices, liquid crystal devices, light-darkening windows, light-darkening visors or eyewear, touch screens, displays, or the like.

The specific details of particular embodiments may be combined in any suitable manner without departing from the spirit and scope of embodiments of the invention. However, other embodiments of the invention may be directed to specific embodiments relating to each individual aspect, or specific combinations of these individual aspects.

The above description of example embodiments of the invention has been presented for the purposes of illustration and description. It is not intended to be exhaustive or to limit the invention to the precise form described, and many modifications and variations are possible in light of the teaching above.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Additionally, details of any specific embodiment may not always be present in variations of that embodiment or may be added to other embodiments. It should be noted that, unless otherwise explicitly noted or required by context, the word “or” is used in this disclosure in a non-exclusive sense.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither, or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a method” includes a plurality of such methods and reference to “the device” includes reference to one or more devices and equivalents thereof known to those skilled in the art, and so forth. The invention has now been described in detail for the purposes of clarity and understanding. However, it will be appreciated that certain changes and modifications may be practice within the scope of the appended claims.

All publications, patents, and patent applications cited herein are hereby incorporated by reference in their entirety for all purposes. None is admitted to be prior art.

1. A bifacial photovoltaic structure configured for receiving and converting a target wavelength or wavelength range of light to electricity, comprising:
a transparent substrate, which is transparent to the target wavelength or wavelength range of light;
a light-transmissive bottom electrode which is transmissive to the target wavelength or wavelength range of light, comprising a first set of conductive lines disposed on the substrate and a first conducting layer comprising a conductive carbon material disposed over the first set of conductive lines;
a perovskite absorber layer disposed over the bottom electrode; and
a transparent top electrode, which is transparent to the target wavelength or wavelength range of light, disposed over the perovskite absorber layer.

2. The photovoltaic structure of claim 1, wherein the top electrode is more transparent than the bottom electrode.

3. The photovoltaic structure of claim 1 wherein the first set of conductive lines comprises silver.

4. The photovoltaic structure of claim 1, wherein the first set of conductive lines comprises copper.

5. (canceled)

6. The photovoltaic structure of claim 1, wherein the first conducting layer comprises carbon nanotubes.

7. The photovoltaic structure of claim 1, wherein the first conducting layer comprises graphene or graphene oxide.

8. The photovoltaic structure of claim 1, wherein the transparent top electrode comprises a second conducting layer.

9. The photovoltaic structure of claim 8, wherein the second conducting layer comprises a transparent conductive oxide, metal nanowires, or carbon nanotubes.

10. (canceled)

11. The photovoltaic structure of claim 8, wherein the transparent top electrode further comprises a second set of conductive lines.

12. The photovoltaic structure of claim 11, wherein the second set of conductive lines is disposed over the second conducting layer

13. The photovoltaic structure of claim 11, wherein the second conducting layer is disposed over the second set of conductive lines.

14. The photovoltaic structure of claim 11, wherein the second set of conductive lines comprises a metal.

15. (canceled)

16. (canceled)

17. The photovoltaic structure of claim 11, wherein the second set of conductive lines have an average width that is less than an average width of the first set of conductive lines.

18. The photovoltaic structure of claim 11, wherein the second set of conductive lines have an average height that is larger than an average height of the first set of conductive lines.

19. (canceled)

20. The photovoltaic structure of claim 1, wherein the first set of conductive lines has an average height in a range of 20-200 nm.

21-23. (canceled)

24. The photovoltaic structure of claim 1, further comprising a first carrier transport layer disposed between the bottom electrode and the perovskite absorber layer and a second carrier transport layer disposed between the perovskite absorber layer and the transparent top electrode.

25-33. (canceled)

34. The photovoltaic structure of claim 24, further comprising an interfacial layer disposed between the bottom electrode and the first carrier transport layer.

35. (canceled)

36. (canceled)

37. The photovoltaic structure of claim 24, further comprising an interfacial layer disposed between the second carrier transport layer and the transparent top electrode.

38. The photovoltaic structure of claim 34, wherein at least one interfacial layer comprises a metal oxide.

39-44. (canceled)

45. The photovoltaic structure of claim 1, wherein the transparent substrate is flexible.

46-48. (canceled)
